(19) United States
(12) Patent Application Publication
(10) Pub. No.: US 2025/0095987 A1
(43) Pub. Date: Mar. 20, 2025

(54) METHOD FOR FORMING SEMICONDUCTOR DIE

(71) Applicant: TAIWAN SEMICONDUCTOR MANUFACTURING COMPANY, LTD., Hsinchu (TW)

(72) Inventors: Shih-Chi FU, Hsinchu County (TW); Kuei-Shun CHEN, Hsinchu City (TW); Hsiang-Yu SU, New Taipei City (TW)

(73) Assignee: TAIWAN SEMICONDUCTOR MANUFACTURING COMPANY, LTD., Hsinchu (TW)

(21) Appl. No.: 18/467,389

(22) Filed: Sep. 14, 2023

(51) Int. Cl. H01L 21/027; G03F 7/00; G03F 9/00; H01L 21/311; H01L 21/768; H01L 23/544

(52) U.S. Cl. CPC H01L 21/027; G03F 7/70141; G03F 9/708; H01L 21/76802; H01L 23/544; H01L 21/31144; H01L 2223/54426; H01L 2223/54453

(57) ABSTRACT

A method includes forming a photoresist layer over a wafer; aligning a first photomask with a first area of the wafer; performing a first exposure process to a first portion of the photoresist layer within the first area of the wafer; aligning a second photomask with a second area of the wafer, wherein aligning the first photomask and aligning the second photomask are performed using an alignment mark within a stitching zone of the wafer, the stitching zone being an overlapping region of the first area and the second area; performing a second exposure process to a second portion of the photoresist layer within the second area of the wafer; and performing a development process to remove the first and second portions of the photoresist layer.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system according to some embodiments of the present disclosure.

FIG. 2 is a top view of a wafer in accordance with some embodiments.

FIGS. 3A to 15 illustrate a semiconductor die in various stages of fabrication in accordance with some embodiments of the present disclosure.

FIG. 16A is a perspective view of a wafer in accordance with some embodiments of the present disclosure.

FIG. 16B is a top view of a wafer in accordance with some embodiments of the present disclosure.

FIG. 16C is a cross-sectional view of a wafer in accordance with some embodiments of the present disclosure.

FIG. 17A is a perspective view of a wafer in accordance with some embodiments of the present disclosure.

FIG. 17B is a top view of a wafer in accordance with some embodiments of the present disclosure.

FIG. 17C is a cross-sectional view of a wafer in accordance with some embodiments of the present disclosure.

FIG. 18 is a cross-sectional view of a wafer in accordance with some embodiments of the present disclosure.

FIG. 19 is a cross-sectional view of a wafer in accordance with some embodiments of the present disclosure.

FIGS. 20A and 20B are top profiles of alignment marks in accordance with some embodiments of the present disclosure.

FIGS. 21A and 21B are top profiles of alignment marks in accordance with some embodiments of the present disclosure.

FIGS. 22A and 22B are top profiles of alignment marks in accordance with some embodiments of the present disclosure.

FIGS. 23A to 24C illustrate a semiconductor die in various stages of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

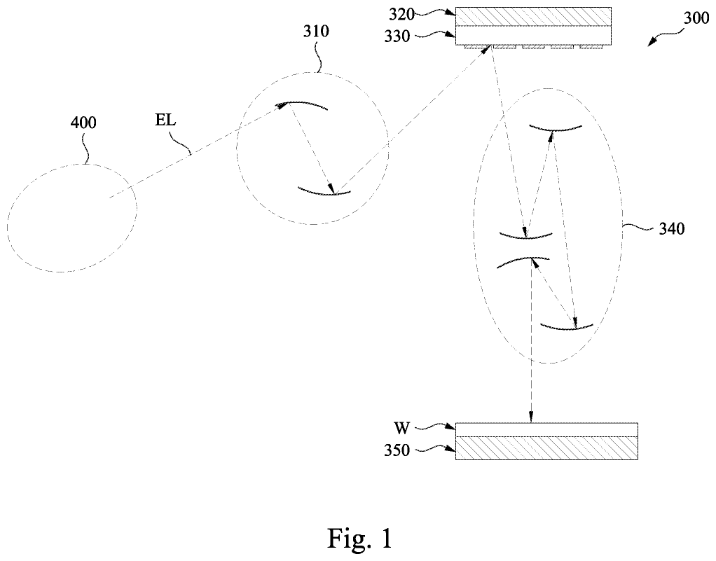

FIG. 1 is a schematic view of a lithography system according to some embodiments of the present disclosure. In some embodiments, the EUV lithography system 300 is designed to expose a resist layer using EUV light (or EUV radiation). The resist layer is a material sensitive to the EUV light. The EUV lithography system 300 employs a radiation source 400 to generate EUV light EL. Accordingly, the radiation source 400 is also referred to as an EUV radiation source 400. The EUV radiation source 400 may utilize a mechanism of laser-produced plasma (LPP) to generate the EUV radiation, which will be further described later.

The EUV lithography system 300 also employs an illuminator 310. In some embodiments, the illuminator 310 includes various reflective optics, such as a single mirror or a mirror system having multiple mirrors, so as to direct the light EL from the radiation source 400 onto a mask 330 secured on a mask stage 320.

In some embodiments, the mask stage 320 includes an electrostatic chuck (e-chuck) used to secure the mask 330. In this context, the terms mask, photomask, and reticle are used interchangeably. In the present embodiment, the mask 330 is a reflective mask.

The EUV lithography system 300 also includes a projection optics module (or projection optics box (POB)) 340 for imaging the pattern of the mask 330 onto a semiconductor substrate W (e.g., wafer) secured on a substrate stage (e.g., wafer stage) 350 of the EUV lithography system 300. The POB 340 includes reflective optics in the present embodiment. The EUV light EL that is directed from the mask 330 and carries the image of the pattern defined on the mask 330 is collected by the POB 340. The illuminator 310 and the POB 340 may be collectively referred to as an optical module of the EUV lithography system 300. In the present embodiment, the semiconductor substrate W is a semiconductor wafer, such as a silicon wafer or other type of wafer to be patterned. The semiconductor substrate W is coated with a resist layer sensitive to the EUV light EL in the present embodiment. Various components including those described above are integrated together and are operable to perform EUV lithography exposing processes.

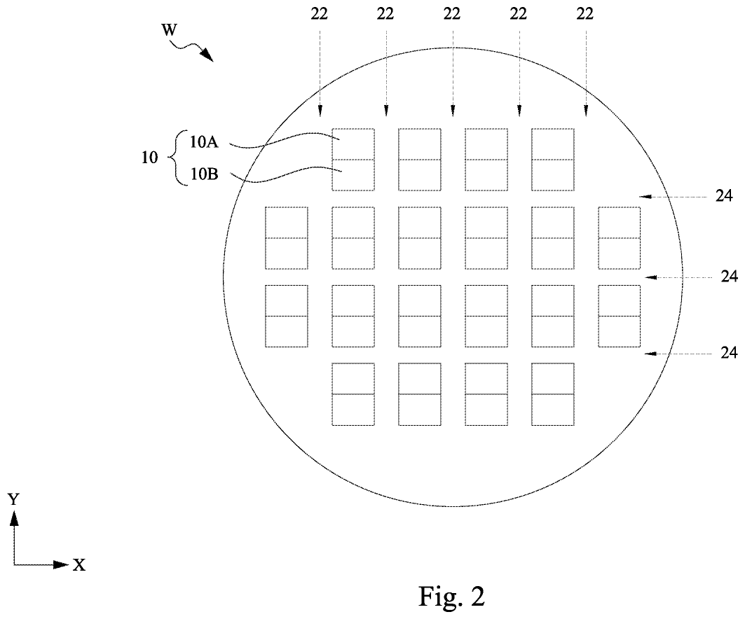

FIG. 2 is a top view of a wafer in accordance with some embodiments. Shown there is a wafer W. In some embodiments, the wafer W may be a semiconductor wafer. The wafer W includes a plurality of die regions 10 (or chip regions). The wafer W includes a plurality of scribe lines 22 and 24, in which each scribe line 22 extends along the X-direction and each scribe line 24 extends along the Y-direction. Each of the die regions 10 of the wafer W is surrounded by a pair of scribe lines 22 and a pair of scribe lines 24. After the semiconductor manufacturing processes performed on the wafer W are finished, the each of the die regions 10 may be singulated, by sawing the wafer through the scribe lines 22 and 24, into individual die.

In the depicted embodiments, the wafer W may be exposed to EUV radiation (light) using a mask (e.g., the mask 330 of FIG. 1) in a lithography system (e.g., the EUV lithography system 300 of FIG. 1). The image of the mask can be transferred to the wafer W multiple times using multiple exposures with the mask. For example, the mask is used in multiple exposure processes to pattern the wafer W, such that the pattern of the mask image region is transferred to various fields of the wafer W (e.g., the die regions 10). Each field (e.g., the die region 10) may correspond to at least one semiconductor device (or at least one integrated circuit device). For example, an exposure tool (such as a stepper or a scanner) processes one field (such as exposing a die region 10 of the wafer W to the mask), then processes the next field (such as exposing another die region 10 of the wafer W to the mask), and so on. In the present example, the wafer W may include a resist layer disposed over a substrate, where the pattern of the mask image region is transferred to the resist layer.

As shown in FIG. 2, each of the die regions 10 may include a first area 10A and a second area 10B adjacent the first area 10A. The first area 10A and the second area 10B may undergo a first exposure process and a second exposure process, respectively. For example, in a first exposure process, a first pattern of a first photomask may be aligned with the first area 10A of the die region 10. Afterwards, the first exposure process is performed by exposing the first area 10A to the first pattern of the photomask, so as to transfer the first pattern of the first photomask to a layer (e.g., photoresist) on the first area 10A of the die region 10. After the first exposure process is finished, a second pattern of a second photomask may be aligned with the second area 10B of the die region 10. Then, the second exposure process is performed by exposing the second area 10B to the second pattern of the second photomask, so as to transfer the second pattern of the photomask to the layer (e.g., photoresist) on the second area 10B of the die region 10. In some embodiments, the first pattern of the first photomask may be different from the second pattern of the second photomask. The first pattern and the second pattern may collectively form a desired pattern (e.g., layout) over the die region 10 of the wafer W.

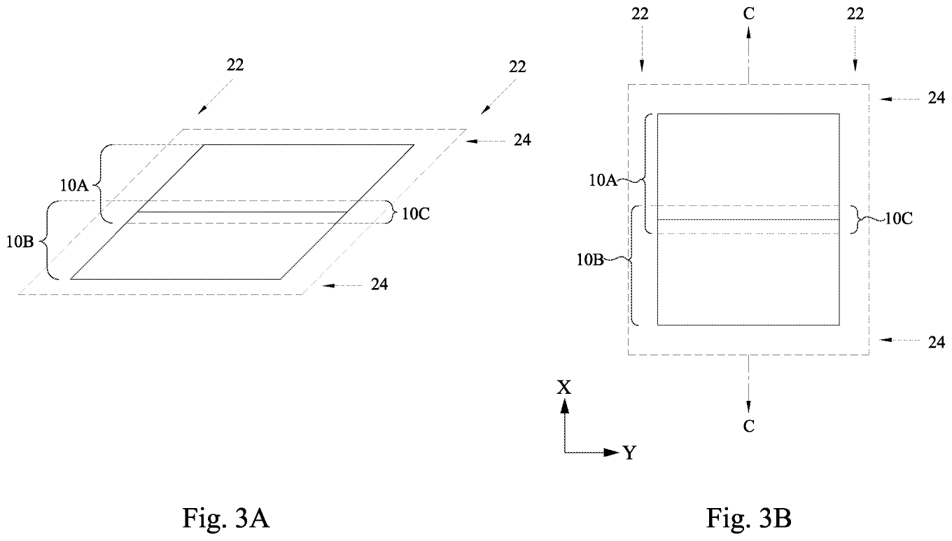

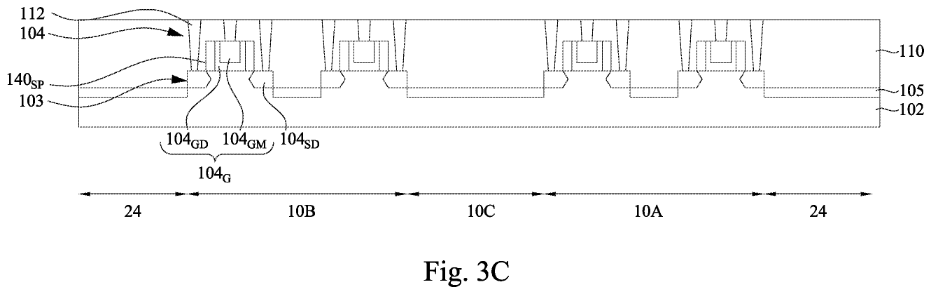

FIGS. 3A to 15 illustrate a semiconductor die in various stages of fabrication in accordance with some embodiments of the present disclosure. Although the views shown in FIGS. 3A to 15 are described with reference to a method, it will be appreciated that the structures shown in FIGS. 3A to 15 are not limited to the method but rather may stand alone separate of the method. Although FIGS. 3A to 15 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 3A, 3B, and 3C, in which FIG. 3A is a perspective view of a wafer, FIG. 3B is a top view of a wafer, and FIG. 3C is a cross-sectional view of a wafer, respectively. In greater detail, the views of FIGS. 3A and 3B illustrate a single die region 10 of a wafer W, and FIG. 3C is a cross-sectional view along line C-C of FIG. 3B. It is noted that some elements of FIGS. 3A, 3B, and 3C are similar to those described with respect to FIG. 2, and such elements are labeled the same.

As shown in FIGS. 3A and 3B, shown there is a die region 10 of a wafer W. The die region 10 is surrounded by scribe lines 22 and 24. The die region 10 includes a first area 10A and a second area 10B. The first area 10A and the second area 10B can also be referred to as first mask field region 10A and a second mask field region 10B, respectively. The first area 10A and the second area 10B have an overlapping region, which may be referred to as a stitching zone 10C. This is because features (such as metal features) that extend from the first area 10A and the second area 10B may be stitched together (or joined) in the stitching zone 10C. In some embodiments, the stitching zone 10C has a strip-like top view, which may include a uniform width. In some embodiments, the first area 10A and the second area 10B may have a substantially same size; although in other embodiments, their size or shape may be different from each other. In some embodiments, the stitching zone 10C is a strip region that continuously extends from one side of the die region 10 to another side of the die region 10.

Higher demagnification is pursued in next-generation EUV tools, particularly when a high numerical aperture (NA) lens system is used. Nevertheless, higher demagnification may necessitate the use of larger mask sizes or lead to a reduced size of the printed field. On the one hand, fabricating a larger mask to compensate is not desirable due to manufacturing complexity, but on the other hand, smaller fields may result in a need for “stitching” or acceptance of substantially reduced throughput, aggravating an already existing problem in EUV lithography. Large chips, such as chips used for graphics processing units (GPUs), may thus need to be stitched together from two or more component patterns to form a complete, composite pattern. The two or more component patterns often require two or more photomasks, and changing photomasks during lithography can undesirably reduce EUVL throughput.

The device region 10 of the wafer W may include active device, such as a diode, a metal-oxide-semiconductor field effect transistor (MOSFET), a complementary MOS (CMOS) transistor, a bipolar junction transistor (BJT), a laterally diffused MOS (LDMOS) transistor, a high power MOS transistor, a fin-like field effect transistor (FinFET), other integrated circuit component, or combination thereof. In other embodiments, the device region 10 may include passive device, such as a resistor, a capacitor, an inductor, or combination thereof. In some embodiments, the scribe lines 22 and 24 and the stitching zone 10C may be free of the active device and the passive device described above.

In FIG. 3C, the wafer W includes a substrate 102. The substrate 102 may comprise, for example, bulk silicon, doped or un-doped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 102 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more active and/or passive devices 104 (illustrated in FIG. 3C as four transistors) are formed over the device region 10 of the substrate 102 of the wafer W. In greater details, the devices 104 may be formed within the first area 10A and the second area 10B of the die region 10. The one or more active and/or passive devices 104 may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also formed as appropriate for a given application. In some embodiments, the scribe lines 22 and 24, and the stitching zone 10C may be free of the one or more active and/or passive devices 104. Accordingly, the first area 10A and the second area 10B may also be referred to as device regions, while the stitching zone 10C can be referred to as non-device region.

In the depicted embodiments, the devices 104 are fin field-effect transistors (FinFET) that are three-dimensional MOSFET structure formed in fin-like strips of semiconductor protrusions referred to as fins 103. The cross-section shown in FIG. 3C is taken along a longitudinal axis of the fin in a direction parallel to the direction of the current flow between the source/drain regions 104_{SD}. The fin 103 may be formed by patterning the substrate 102 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 103 by etching a trench into the substrate 102 using, for example, reactive ion etching (RIE). In some other embodiments, the devices 104 may also be planar transistors or gate-all-around (GAA) transistors.

Shallow trench isolation (STI) regions 105 formed on opposing sidewalls of the fin 103 are illustrated in FIG. 3C. STI regions 105 may be formed by depositing one or more dielectric materials (e.g., silicon oxide) to completely fill the trenches around the fins and then recessing the top surface of the dielectric materials. The dielectric materials of the STI regions 105 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 105 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 105 such that an upper portion of fins 103 protrudes from surrounding insulating STI regions 105. In some cases, the patterned hard mask used to form the fins 103 may also be removed by the planarization process.

In some embodiments, a gate structure 104G of the device 104 illustrated in FIG. 3C is a high-k metal gate (HKMG) gate structure that may be formed using a gate-last process flow. In a gate-last process flow, a sacrificial dummy gate structure (not shown) is formed after forming the STI regions 105. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 105. As described in greater detail below, the dummy gate structure may be replaced by the metal gate structure 104G as illustrated in FIG. 3C. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 3C, source/drain regions 104_{SD} and spacers 104_{SP} of the device 104 are formed, for example, self-aligned to the dummy gate structures. Spacers 104_{SP} may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 104_{SP} along the sidewalls of the dummy gate structures extending laterally onto a portion of the surface of the fin 103.

Source/drain regions 104_{SD} are semiconductor regions in direct contact with the semiconductor fin 103. In some embodiments, the source/drain regions 104_{SD} may comprise heavily-doped regions and relatively lightly-doped drain extensions, or LDD regions. Generally, the heavily-doped regions are spaced away from the dummy gate structures using the spacers 104_{SP}, whereas the LDD regions may be formed prior to forming spacers 104_{SP} and, hence, extend under the spacers 104_{SP} and, in some embodiments, extend further into a portion of the semiconductor fin 103 below the dummy gate structure. The LDD regions may be formed, for example, by implanting dopants (e.g., As, P, B, In, or the like) using an ion implantation process.

The source/drain regions 104_{SD} may comprise an epitaxially grown region. For example, after forming the LDD regions, the spacers 104_{SP} may be formed and, subsequently, the heavily-doped source and drain regions may be formed self-aligned to the spacers 104_{SP} by first etching the fins to form recesses, and then depositing a crystalline semiconductor material in the recess by a selective epitaxial growth (SEG) process that may fill the recess and may extend further beyond the original surface of the fin 103 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source/drain regions 104_{SD} either in situ during SEG, or by an ion implantation process performed after the SEG, or by a combination thereof.

Once the source/drain regions 104_{SD} are formed, a first ILD layer (e.g., lower portion of the ILD layer 110) is deposited over the source/drain regions 104_{SD}. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The metal gate structures 104G, illustrated in FIG. 3C, may then be formed by first removing the dummy gate structures using one or more etching techniques, thereby creating recesses between respective spacers 104_{SP}. Next, a replacement gate dielectric layer 104_{GD} comprising one more dielectrics, followed by a replacement gate metal layer 104_{GM} comprising one or more metals, are deposited to completely fill the recesses. Excess portions of the gate dielectric layer 104_{GD} and gate metal layer 104_{GM} may be removed from over the top surface of first ILD using, for example, a CMP process. The resulting structure, as illustrated in FIG. 3C, may include remaining portions of the gate dielectric layer 104_{GD} and gate metal layer 104_{GM} inlaid between respective spacers 104_{SP}.

The gate dielectric layer 104_{GD} includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer 104_{GM} may be a multilayered metal gate stack comprising a barrier layer, a work function layer, and a gate-fill layer formed successively on top of gate dielectric layer 104_{GD}. Example materials for a barrier layer include TIN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the metal gate structure 104G, a second ILD layer is deposited over the first ILD layer, and these ILD layers are in combination referred to as the ILD layer 110, as illustrated in FIG. 3C. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, physical vapor deposition (PVD), ALD, PEALD, PECVD, SACVD, FCVD, spin-on, and/or the like, or a combination thereof.

As illustrated in FIG. 3C, contacts 112 are formed to make electrical connections to the metal gate structure 104G and the source/drain regions 104_{SD} of devices 104. The contacts 112 may be formed using photolithography, etching and deposition techniques.

For example, a patterned mask may be formed over the ILD layer 110 and used to etch openings that extend through the ILD layer 110 to expose the gate structure 104G as well as the source/drain regions 104_{SD}. Thereafter, conductive liner may be formed in the openings in the ILD layer 110. Subsequently, the openings are filled with a conductive fill material. The liner comprises barrier metals used to reduce out-diffusion of conductive materials from the contacts 112 into the surrounding dielectric materials. In some embodiments, the liner may comprise two barrier metal layers. The first barrier metal comes in contact with the semiconductor material in the source/drain regions 104_{SD} and may be subsequently chemically reacted with the heavily-doped semiconductor in the source/drain regions 104_{SD} to form a low resistance ohmic contact, after which the unreacted metal may be removed. For example, if the heavily-doped semiconductor in the source/drain regions 104_{SD} is silicon or silicon-germanium alloy semiconductor, then the first barrier metal may comprise Ti, Ni, Pt, Co, other suitable metals, or their alloys, and may form silicide with the source/drain regions 104_{SD}. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 110.

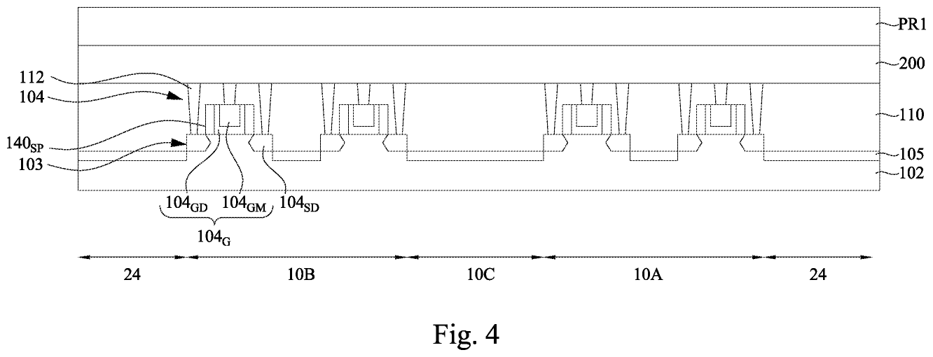

Reference is made to FIG. 4. An inter-metal dielectric (IMD) layer 200 is formed over the ILD layer 110. In some embodiments, the IMD layer 200 may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. In some embodiments, an etch stop layer (not shown) may be formed over the ILD layer 110 prior to forming the IMD layer. A photoresist layer PR1 is then formed over the IMD layer 200.

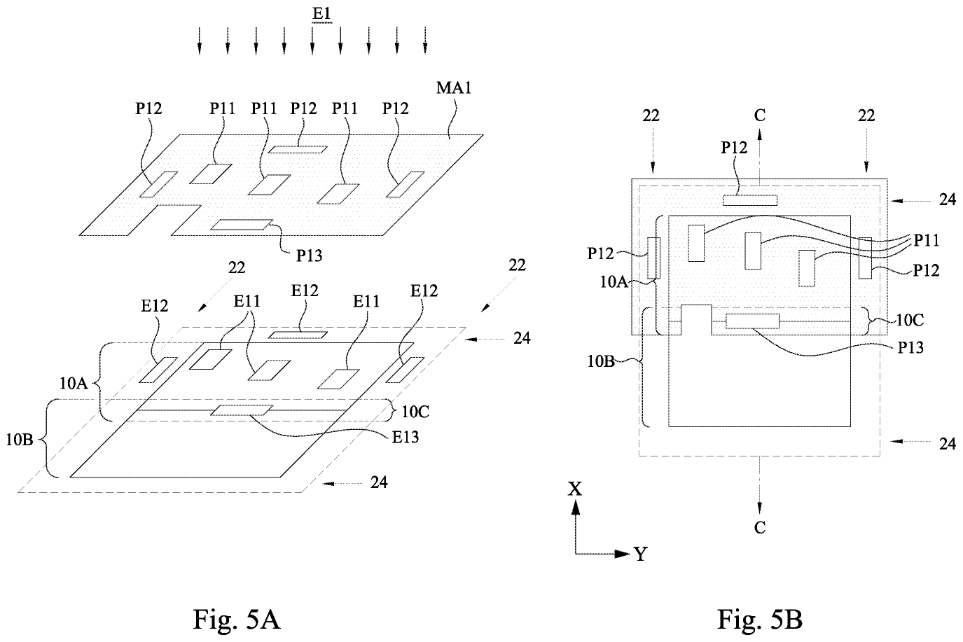

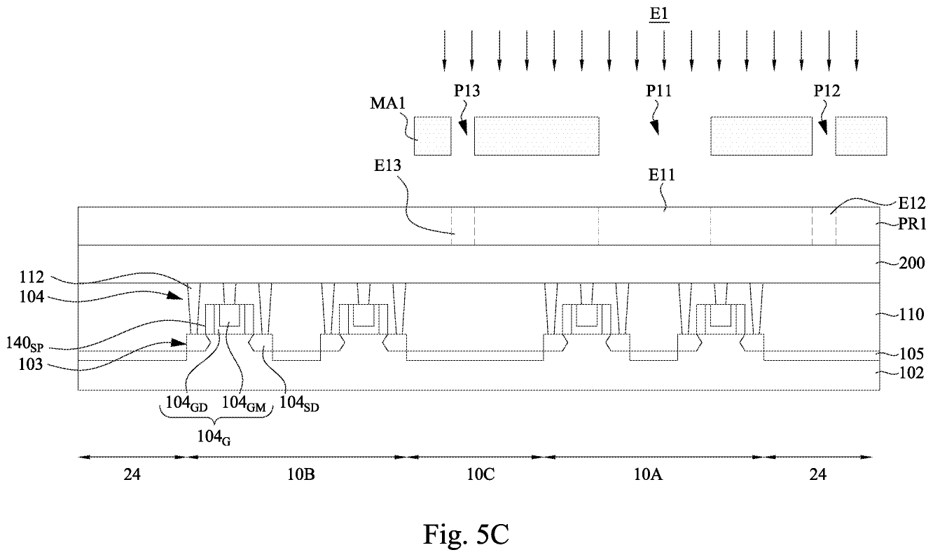

Reference is made to FIGS. 5A, 5B, and 5C, in which FIG. 5A is a perspective view of a wafer, FIG. 5B is a top view of a wafer, and FIG. 5C is a cross-sectional view along line C-C of FIG. 5B, respectively. An exposure process E1 is performed. During the exposure process E1, a photomask MA1 is used to expose the first area 10A of the die region 10. In greater detail, the photomask MAL is used to expose the first area 10A and the stitching zone 10C. In some embodiments, the projected region of the photomask MA1 over the wafer W only covers the first area 10A and the stitching zone 10C. That is, the projected region of the photomask MA1 does not cover both the first area 10A and the second area 10B. In some embodiments, the projected region of the photomask MA1 may also cover the portions of scribe lines 22 and 24 adjacent to the first area 10A. In some embodiments, the second area 10B does not undergo the exposure process E1. Prior to performing the exposure process E1, the photomask MA1 is properly aligned with the first area 10A.

In some embodiments, the photomask MA1 may include layout patterns P11, alignment mark patterns P12 and P13. The layout patterns P11 and the alignment mark patterns P12 and P13 may be openings in the photomask MA1, such that radiation may pass through the openings of the photomask MA1 and expose the corresponding regions of the photoresist layer PR1 within the first area 10A. In greater detail, the layout patterns P11 correspond to (e.g., above) the first area 10A of the die region 10, the alignment mark patterns P12 correspond to (e.g., above) the scribe lines 22 and 24, and the alignment mark pattern P13 corresponds to (e.g., above) the stitching zone 10C.

During the exposure process E1, the photoresist layer PR1 is exposed to radiation (e.g., EUV light) through the photomask MA1, so as to form exposed regions E11, E12, and E13 in the photoresist layer PR1. The patterns of the exposed regions E11 correspond to the layout patterns P11, the patterns of the exposed regions E12 correspond to the alignment mark patterns P12, and the patterns of the exposed regions E13 correspond to the alignment mark patterns P13.

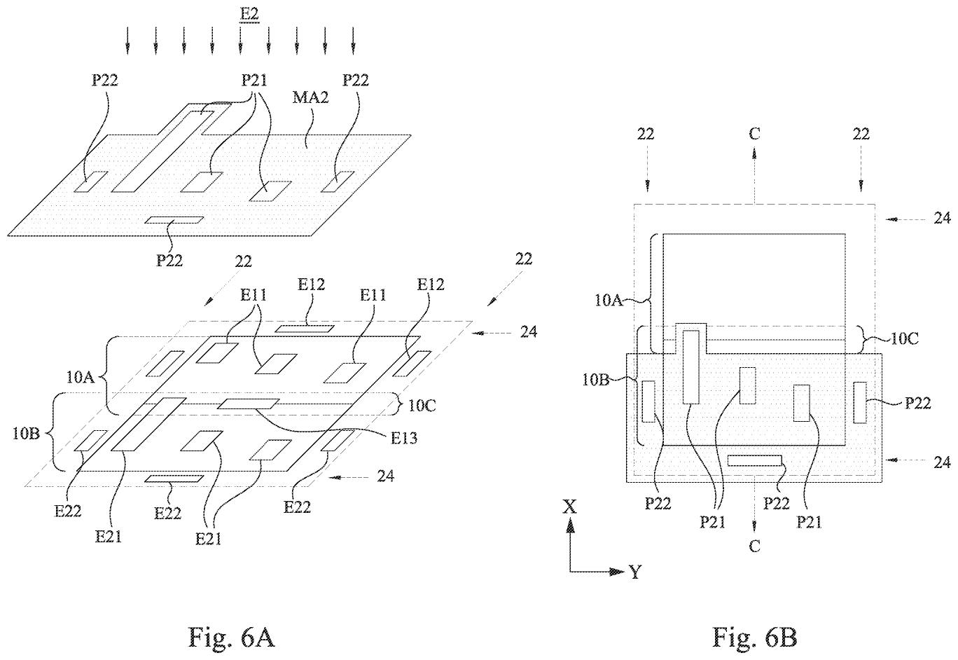

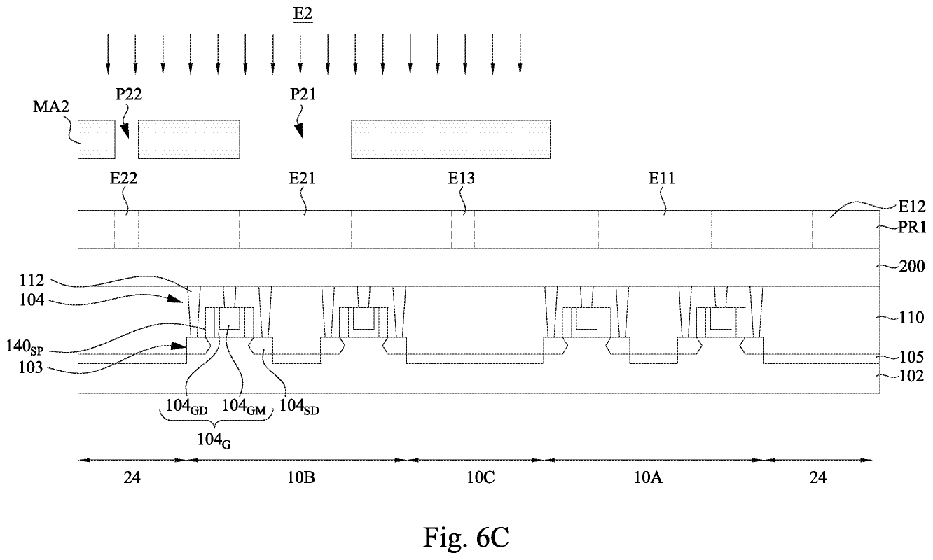

Reference is made to FIGS. 6A, 6B, and 6C, in which FIG. 6A is a perspective view of a wafer, FIG. 6B is a top view of a wafer, and FIG. 6C is a cross-sectional view along line C-C of FIG. 6B, respectively. After the exposure process E1 discussed in FIGS. 5A to 5C is finished, an exposure process E2 is performed. During the exposure process E2, a photomask MA2 is used to expose the second area 10B of the die region 10. In greater detail, the photomask MA2 is used to expose the second area 10B and the stitching zone 10C. In some embodiments, the projection region of the photomask MA2 only covers the second area 10B and the stitching zone 10C. That is, the projection region of the photomask MA2 does not cover both the first area 10A and the second area 10B. In some embodiments, the projection region of the photomask MA2 may also cover the portions of scribe lines 22 and 24 adjacent to the second area 10B. In some embodiments, the first area 10A does not undergo the exposure process E2.

In some embodiments, the photomask MA2 may include layout patterns P21 and alignment mark patterns P22. The layout patterns P21 and the alignment mark patterns P22 may be openings in the photomask MA2, such that radiation may pass through the openings of the photomask MA2 and expose the corresponding regions of the photoresist layer PR1 within the second area 10B. In greater detail, the layout patterns P21 correspond to (e.g., above) the second area 10B of the die region 10, and the alignment mark patterns P22 correspond to (e.g., above) the scribe lines 22 and 24.

During the exposure process E2, the photoresist layer PR1 is exposed to radiation (e.g., EUV light) through the photomask MA2, so as to form exposed regions E21 and E22 in the photoresist layer PR1. The patterns of the exposed regions E21 correspond to the layout patterns P21, and the patterns of the exposed regions E22 correspond to the alignment mark patterns P22.

As shown in FIG. 6B, the photomask MA2 may include a protrusion portion, in which the projection region of the protrusion portion on the wafer may overlap the stitching zone 10C. In some embodiments, one of the layout pattern P21 may extend into the protrusion portion, and therefore the corresponding exposed region E21 may extend into the stitching zone 10C.

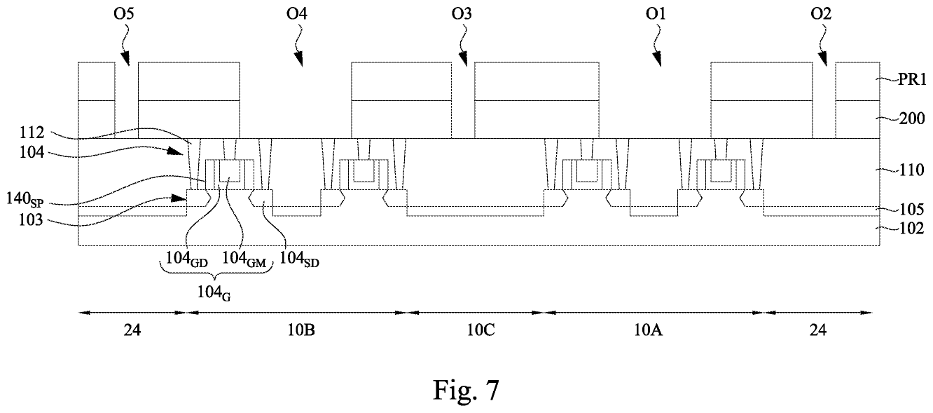

Reference is made to FIG. 7. After the exposure processes E1 and E2 are finished, a development process is performed to remove the exposed portions of photoresist layer PR1. In greater detail, the exposed regions E11, E12, E13, E21, and E22 in the photoresist layer PR1 are removed during the development process. As a result, a plurality of openings that correspond to the patterns of the exposed regions E11, E12, E13, E21, and E22 are formed in the developed photoresist layer PR1. As a result, the patterns of the photomask MA1 and the patterns of the photomask MA2 are transferred to the photoresist layer PR1.

The IMD layer 200 is then patterned using the developed photoresist layer PR1 as an etch mask. For example, an etching process is performed to the IMD layer 200 through the openings of the developed photoresist layer PR1. As a result, the patterns of the photomask MA1 and the patterns of the photomask MA2 are transferred to the IMD layer 200 through the developed photoresist layer PR1.

In the cross-sectional view of FIG. 7, as a result of the etching process, openings O1, O2, O3, O4, and O5 are formed in the IMD layer 200. The pattern of the opening(s) O1 may correspond to the layout patterns P11. The pattern of the opening(s) O2 may correspond to the alignment mark patterns P12. The pattern of the opening(s) O3 may correspond to the alignment mark pattern P13. The pattern of the opening(s) O4 may correspond to the layout patterns P21. The pattern of the opening(s) O5 may correspond to the alignment mark patterns P22.

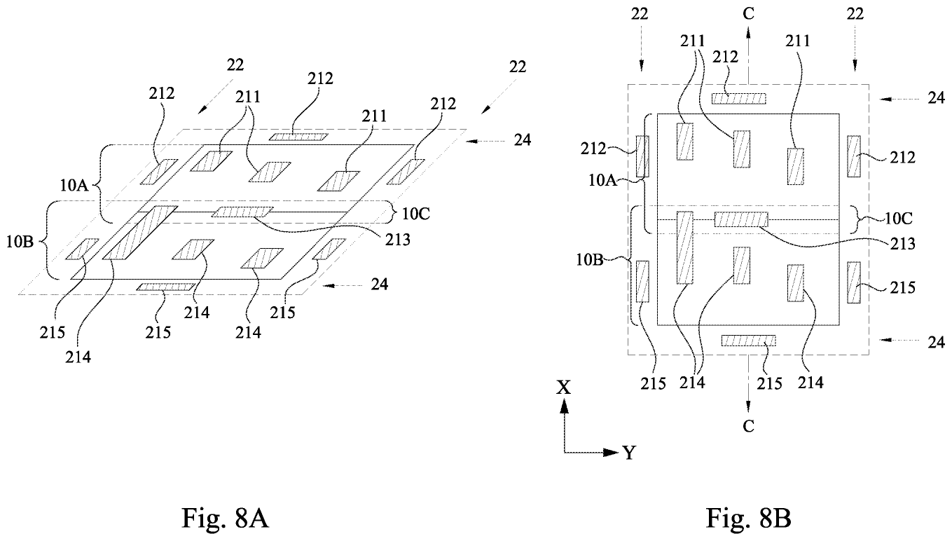

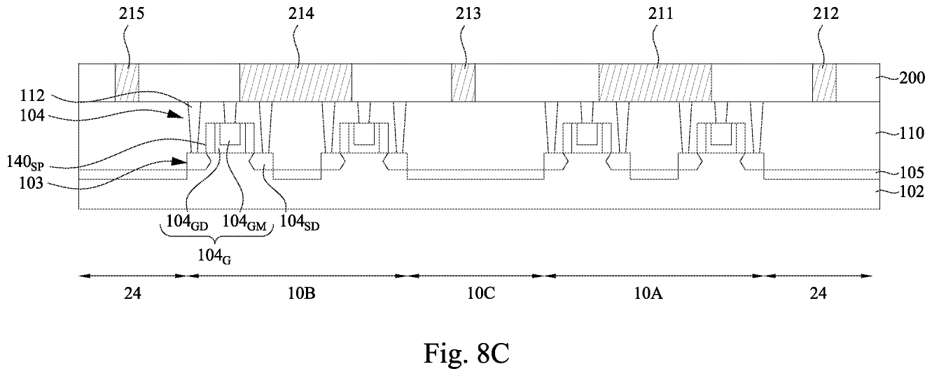

Reference is made to FIGS. 8A, 8B, and 8C, in which FIG. 8A is a perspective view of a wafer, FIG. 8B is a top view of a wafer, and FIG. 8C is a cross-sectional view along line C-C of FIG. 8B, respectively. The photoresist layer PR1 is removed from the IMD layer 200 using suitable process, such as ashing or striping. Conductive material, such as metal, is formed in the openings O1, O2, O3, O4, and O5 of the IMD layer 200. Afterwards, a planarization process, such as CMP, is performed to remove excess conductive material until the IMD layer 200 is exposed. The conductive material may include metal such as copper (Cu), aluminum (Al), tungsten (W), combinations thereof, or the like, and may be formed using suitable deposition process.

Portions of the conductive material filled in the openings O1, O2, O3, O4, and O5 of the IMD layer 200 can be referred to as metal features 211, alignment marks 212, alignment mark 213, metal features 214, and alignment marks 215, respectively. In which the patterns of the metal features 211, the alignment marks 212, the alignment mark 213, the metal features 214, and the alignment marks 215 may inherit the patterns of the layout patterns P11, the alignment mark patterns P12, the alignment mark pattern P13, the layout patterns P21, and the alignment mark patterns P22 as described above.

In some embodiments, the metal features 211 are electrically connected to the devices 104 within first area 10A of the die region 10 through the contacts 112. On the other hand, the metal features 214 are electrically connected to the devices 104 within second area 10B of the die region 10 through the contacts 112. In some embodiments, the alignment marks 212, 213, and 215 are electrically isolated from the devices 104. In some embodiments, the alignment mark 213 is only within the stitching zone 10C, and does not extend into the first area 10A and the second area 10B. In some embodiments, one of the metal features 214 may extend into the stitching zone 10C.

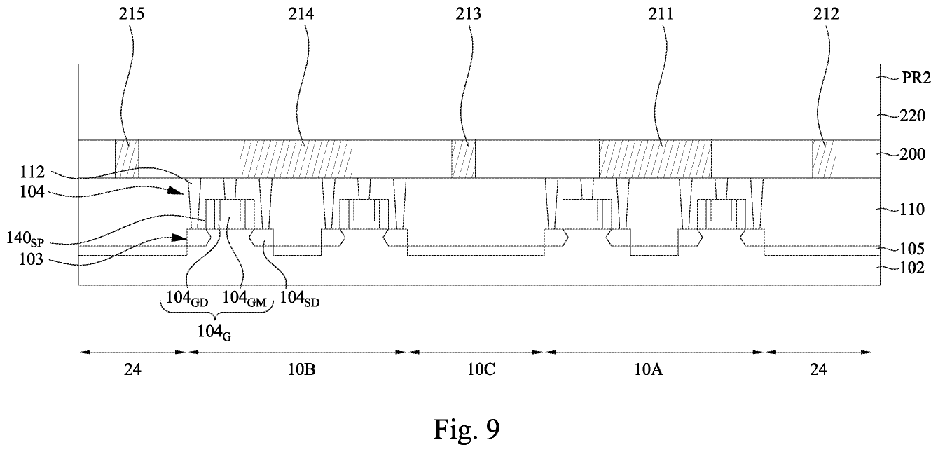

Reference is made to FIG. 9. An inter-metal dielectric (IMD) layer 220 is formed over the IMD layer 200. In some embodiments, material and formation method of the IMD layer 220 may be similar to those described with respect to the IMD layer 200, and thus relevant details will not be repeated for brevity. A photoresist layer PR2 is then formed over the IMD layer 220.

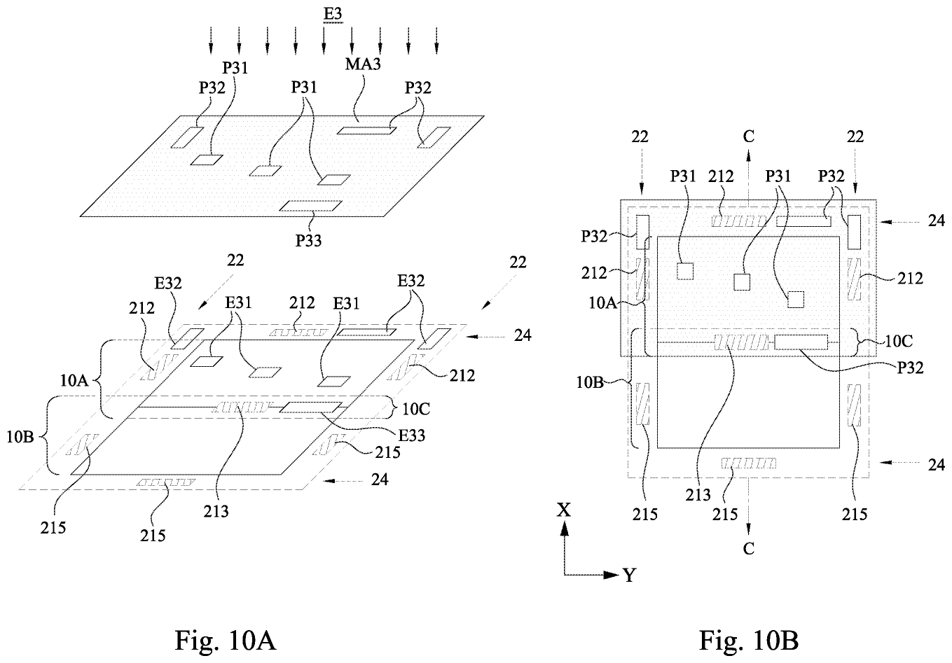

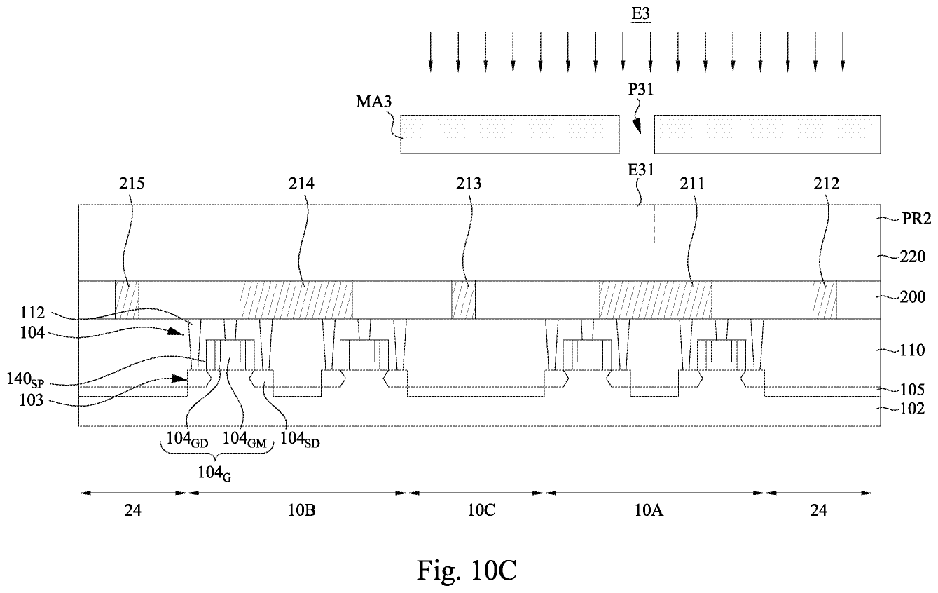

Reference is made to FIGS. 10A, 10B, and 10C, in which FIG. 10A is a perspective view of a wafer, FIG. 10B is a top view of a wafer, and FIG. 10C is a cross-sectional view along line C-C of FIG. 10B, respectively. It is noted that the alignment marks 212, 213, and 215 in the underlying IMD layer 200 are drawn in dash-line in FIGS. 10A and 10B. An exposure process E3 is performed. During the exposure process E3, a photomask MA3 is used to expose the first area 10A of the die region 10. In greater detail, the photomask MA1 is used to expose the first area 10A and the stitching zone 10C. In some embodiments, the projection region of the photomask MA3 only covers the first area 10A and the stitching zone 10C. That is, the projection region of the photomask MA3 does not cover both the first area 10A and the second area 10B. In some embodiments, the projection region of the photomask MA3 may also cover the portions of scribe lines 22 and 24 adjacent to the first area 10A. In some embodiments, the second area 10B does not undergo the exposure process E3.

In some embodiments, prior to performing the exposure process E3, the photomask MA3 is aligned with the underlying metal features 211 of the IMD layer 200 within the first area 10A using the alignment marks 212 and/or 213 in the IMD layer 200. For example, the photomask MA3 is aligned with the underlying metal features 211 of the IMD layer 200 within the first area 10A using the alignment mark 213 within the stitching zone 10C. Once the photomask MA3 is aligned with the metal features 211 of the IMD layer 200, the exposure process E3 may be performed.

In some embodiments, the photomask MA3 may include layout patterns P31, alignment mark patterns P32 and P33. The layout patterns P31 and the alignment mark patterns P32 and P33 may be openings in the photomask MA1, such that radiation may pass through the openings of the photomask MA3 and expose the corresponding regions of the photoresist layer PR2 within the first area 10A. In greater detail, the layout patterns P31 correspond to (e.g., above) the first area 10A of the die region 10, the alignment mark patterns P32 correspond to (e.g., above) the scribe lines 22 and 24, and the alignment mark pattern P33 corresponds to (e.g., above) the stitching zone 10C.

During the exposure process E3, the photoresist layer PR2 is exposed to radiation (e.g., EUV light) through the photomask MA3, so as to form exposed regions E31, E32, and E33 in the photoresist layer PR2. The patterns of the exposed regions E31 correspond to the layout patterns P31, the patterns of the exposed regions E32 correspond to the alignment mark patterns P32, and the patterns of the exposed regions E13 correspond to the alignment mark patterns P33.

In some embodiments, the exposed regions E31 may overlap with the corresponding metal features 211 in the IMD layer 200. For example, in FIG. 10C, at least an exposed region E31 vertically overlaps the corresponding metal features 211 in the IMD layer 200.

On the other hand, the exposed regions E32 and E33 may not overlap the alignment marks 212 and 213 in the IMD layer 200. For example, as shown in FIGS. 10A and 10B, the exposed region E33 does not overlap the alignment mark 213.

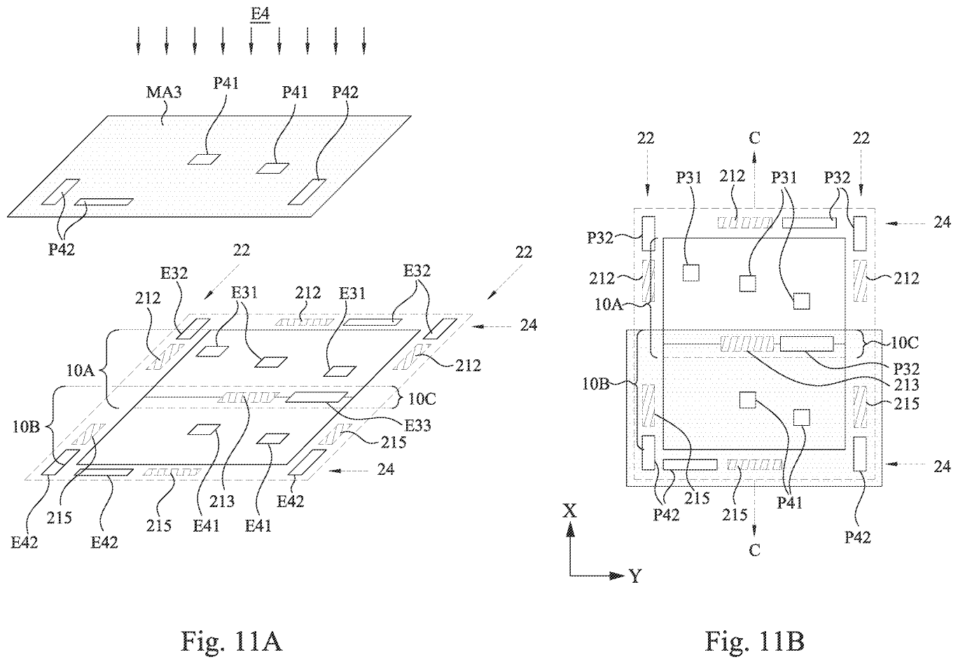

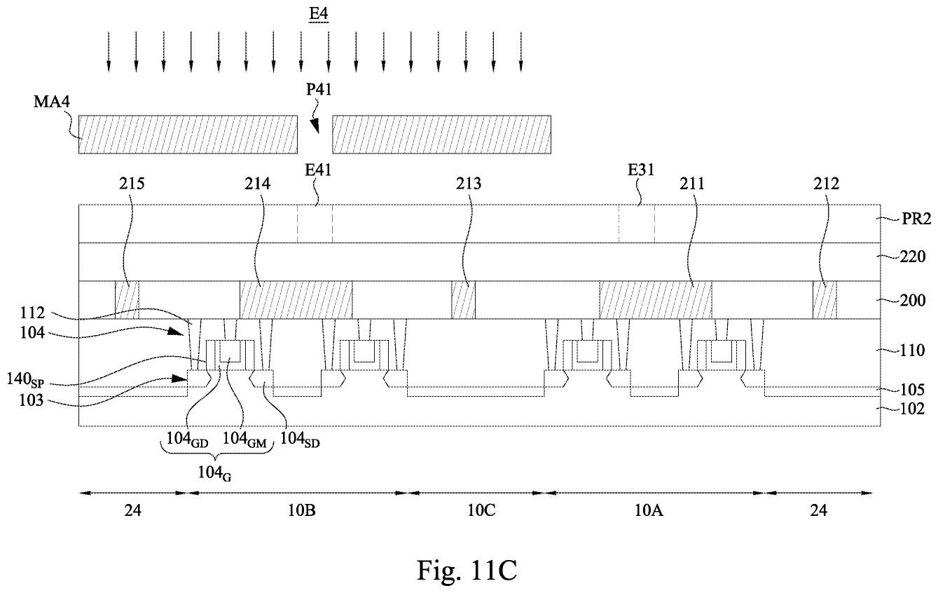

Reference is made to FIGS. 11A, 11B, and 11C, in which FIG. 11A is a perspective view of a wafer, FIG. 11B is a top view of a wafer, and FIG. 11C is a cross-sectional view along line C-C of FIG. 11B, respectively. After the exposure process E3 discussed in FIGS. 10A to 10C is finished, an exposure process E4 is performed. During the exposure process E4, a photomask MA4 is used to expose the first area 10A of the die region 10. In greater detail, the photomask MA4 is used to expose the second area 10B and the stitching zone 10C. In some embodiments, the projection region of the photomask MA4 only covers the second area 10B and the stitching zone 10C. That is, the projection region of the photomask MA4 does not cover both the first area 10A and the second area 10B. In some embodiments, the projection region of the photomask MA4 may also cover the portions of scribe lines 22 and 24 adjacent to the second area 10B. In some embodiments, the first area 10A does not undergo the exposure process E4.

In some embodiments, prior to performing the exposure process E4, the photomask MA4 is aligned with the underlying metal features 214 of the IMD layer 200 within the second area 10B using the alignment marks 213 and/or 215 in the IMD layer 200. For example, the photomask MA4 is aligned with the underlying metal features 214 of the IMD layer 200 within the second area 10B using the alignment mark 213 within the stitching zone 10C. Once the photomask MA4 is aligned with the metal features 214 of the IMD layer 200, the exposure process E4 may be performed.

In some embodiments, the photomask MA4 may include layout patterns P41, alignment mark patterns P42. The layout patterns P41 and the alignment mark patterns P42 may be openings in the photomask MA4, such that radiation may pass through the openings of the photomask MA4 and expose the corresponding regions of the photoresist layer PR2 within the second area 10B. In greater detail, the layout patterns P41 correspond to (e.g., above) the second area 10B of the die region 10, the alignment mark patterns P42 correspond to (e.g., above) the scribe lines 22 and 24.

During the exposure process E4, the photoresist layer PR2 is exposed to radiation (e.g., EUV light) through the photomask MA4, so as to form exposed regions E41 and E42 in the photoresist layer PR2. The patterns of the exposed regions E41 correspond to the layout patterns P41, and the patterns of the exposed regions E42 correspond to the alignment mark patterns P42.

In some embodiments, the exposed regions E41 may overlap with the corresponding metal features 214 in the IMD layer 200. For example, in FIG. 11C, at least an exposed region E41 vertically overlaps the corresponding metal features 211 in the IMD layer 200.

On the other hand, the exposed regions E42 may not overlap the alignment marks 215 in the IMD layer 200. For example, as shown in FIGS. 11A and 11B, the exposed region E42 does not overlap the alignment marks 215.

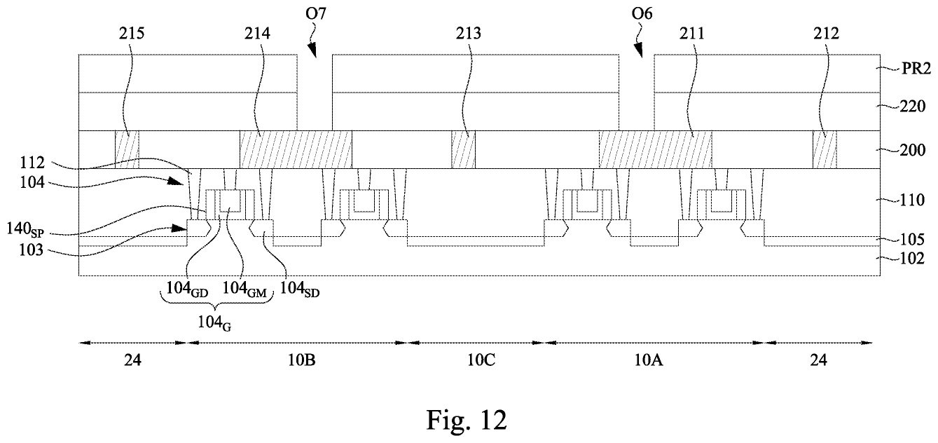

Reference is made to FIG. 12. After the exposure processes E3 and E4 are finished, a development process is performed to remove the exposed portions of photoresist layer PR2. In greater detail, the exposed regions E31, E32, E33, E41, and E42 in the photoresist layer PR2 are removed during the development process. As a result, a plurality of openings that correspond to the patterns of the exposed regions E31, E32, E33, E41, and E42 are formed in the developed photoresist layer PR2. As a result, the patterns of the photomask MA3 and the patterns of the photomask MA4 are transferred to the photoresist layer PR2.

The IMD layer 220 is then patterned using the developed photoresist layer PR2 as an etch mask. For example, an etching process is performed to the IMD layer 220 through the openings of the developed photoresist layer PR2. As a result, the patterns of the photomask MA3 and the patterns of the photomask MA4 are transferred to the IMD layer 220 through the developed photoresist layer PR2.

In the cross-sectional view of FIG. 12, as a result of the etching process, openings O6 and O7 are formed in the IMD layer 220. The pattern of the opening(s) O6 may correspond to the layout patterns P31. The pattern of the opening(s) O7 may correspond to the layout patterns P41. Although not shown in FIG. 12, openings that correspond to the alignment mark patterns P32, P33, and P42 may also be formed in the IMD layer 220.

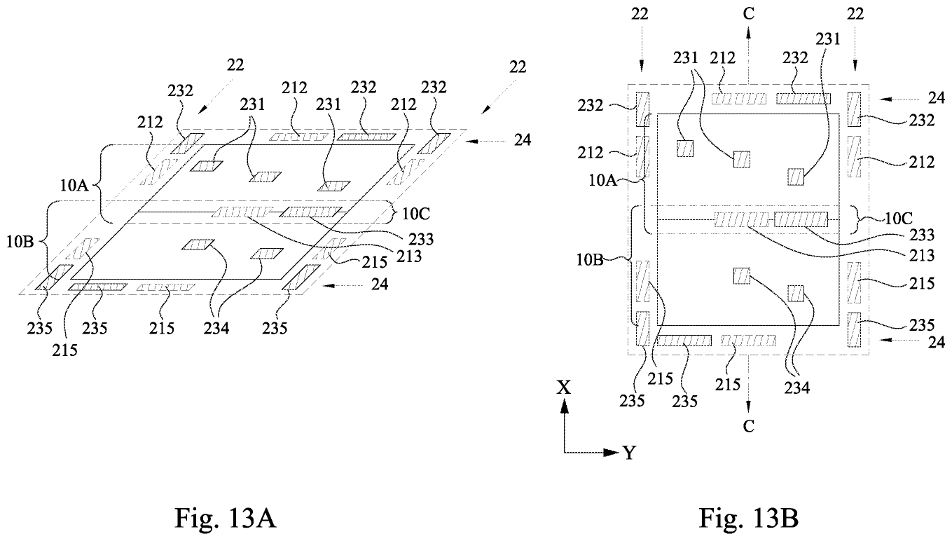

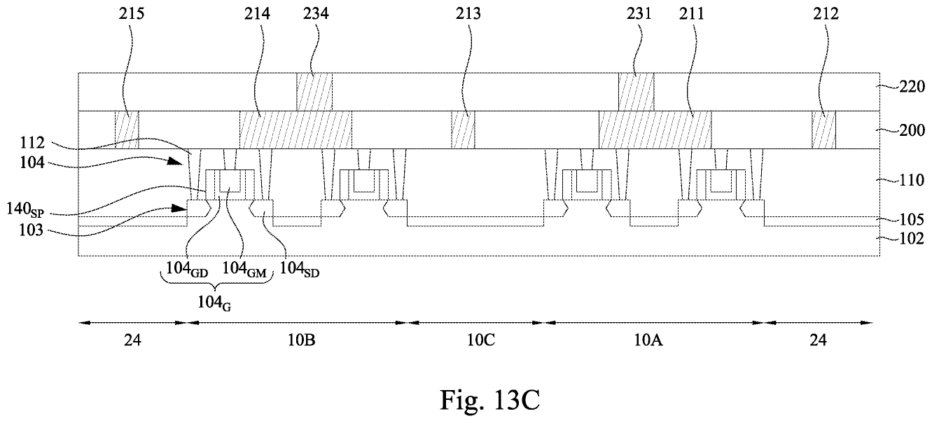

Reference is made to FIGS. 13A, 13B, and 13C, in which FIG. 13A is a perspective view of a wafer, FIG. 13B is a top view of a wafer, and FIG. 13C is a cross-sectional view along line C-C of FIG. 13B, respectively. The photoresist layer PR2 is removed from the IMD layer 220 using suitable process, such as ashing or striping. Conductive material, such as metal, is formed in the openings (e.g., openings O6 and O7) of the IMD layer 220. Afterwards, a planarization process, such as CMP, is performed to remove excess conductive material until the IMD layer 220 is exposed. The conductive material may include metal such as copper (Cu), aluminum (Al), tungsten (W), combinations thereof, or the like, and may be formed using suitable deposition process.

Portions of the conductive material filled in the openings of the IMD layer 220 can be referred to as metal features 231, alignment marks 232, alignment mark 233, metal features 234, and alignment marks 235, respectively. The patterns of the metal features 231, the alignment marks 232, the alignment mark 233, the metal features 234, and the alignment marks 235 may inherit the patterns of the layout patterns P31, the alignment mark patterns P32, the alignment mark pattern P33, the layout patterns P41, and the alignment mark patterns P42 as described above.

In some embodiments, the metal features 231 are in contact with the corresponding metal features 211 in the IMD layer 200. On the other hand, the metal features 234 are in contact with the corresponding metal features 214 in the IMD layer 200. That is, the metal features 231 and 234 may be electrically connected to the devices 104 within the first area 10A and the second area 10B, respectively. In some embodiments, the alignment marks 232, 233, and 235 are electrically isolated from the devices 104.

Moreover, the alignment marks 232 and 233 may not overlap the alignment marks 212 and 213 in the IMD layer 200. Similarly, the alignment marks 235 may not overlap the alignment marks 215 in the IMD layer 200.

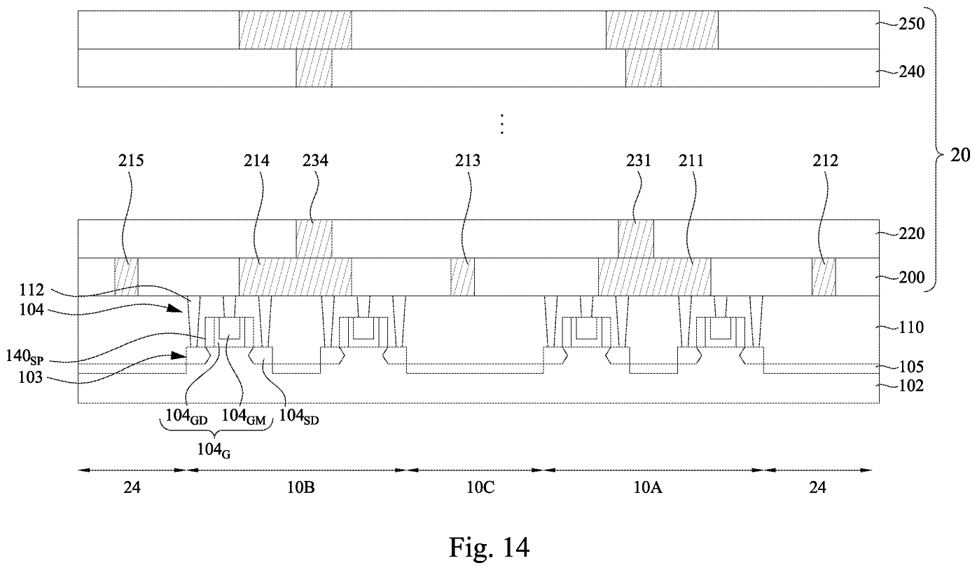

Reference is made to FIG. 14. A plurality of IMD layers may be formed over the IMD layer 220. For example, shown there are IMD layers 240 and 250 formed over the IMD layers 220. In some embodiments, each of the IMD layers 240 and 250 may include metal features and alignment marks that are similar to those described with respect to the IMD layers 200 and 220, and the formation methods of the IMD layers 240 and 250 may also be similar to those described with respect to the IMD layers 200 and 220. In some embodiments, although not shown in FIG. 14, a plurality of IMD layers may be formed between the IMD layer 220 and the IMD layer 240. In some embodiments, the IMD layers, such as the IMD layers 200, 220, 240, and 250 may be collectively referred to as back-end-of line (BEOL) structure 20. In some embodiments, the number of IMD layers (e.g., the IMD layers 200, 220, 240, and 250) is merely used to explain, the present disclosure is not limited thereto. In other embodiments, more or less IMD layers may also be applied.

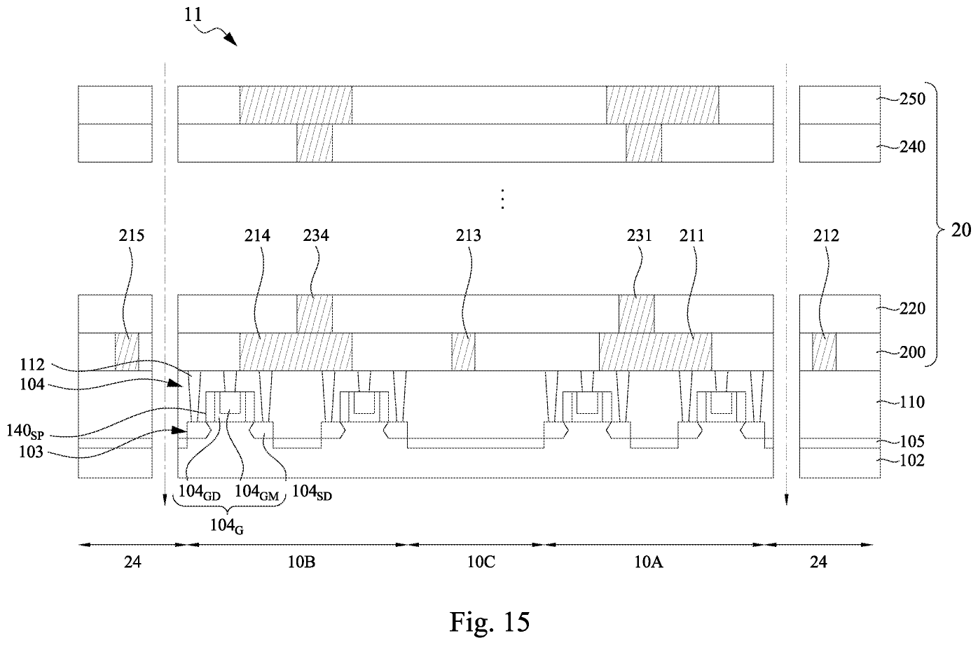

Reference is made to FIG. 15. A die singulation process is performed. For example, the wafer W (see FIG. 2) is cut (or sawed) through the scribe lines 22 and 24, such that each of the die region 10 of the wafer W is singulated into individual semiconductor die 11. During the die singulation process, the alignment marks within the scribe lines 22 and 24 (e.g., the alignment marks 212, 215, 232, and 235 as described above) may be removed (or destroyed). Accordingly, these alignment marks may not be present in the semiconductor die 11 after the die singulation process. On the other hand, the alignment marks within the stitching zone 10C (e.g., the alignment marks 213 and 233 as described above) may remain in the semiconductor die 11 after the die singulation process. Accordingly, such alignment marks (e.g., the alignment marks 213 and 233) may be referred to as in-die alignment marks or in-chip alignment marks.

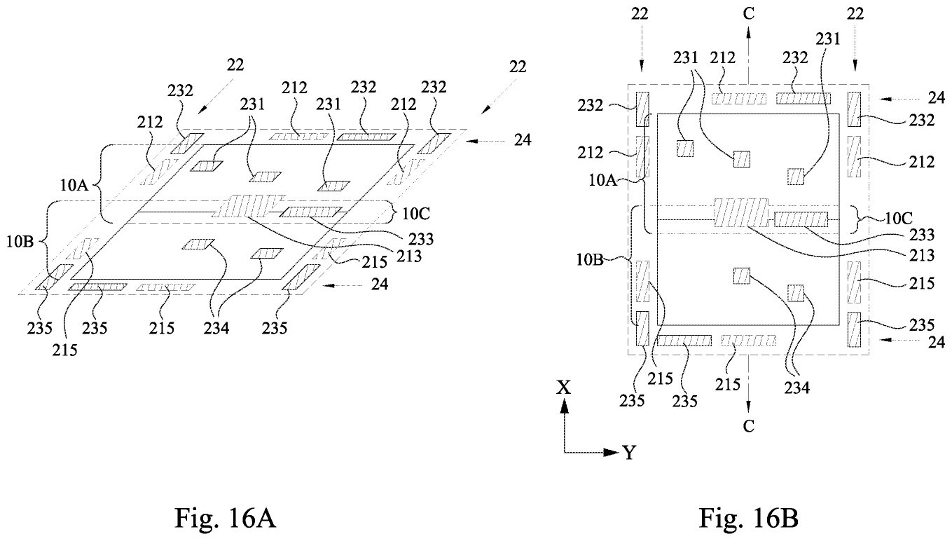

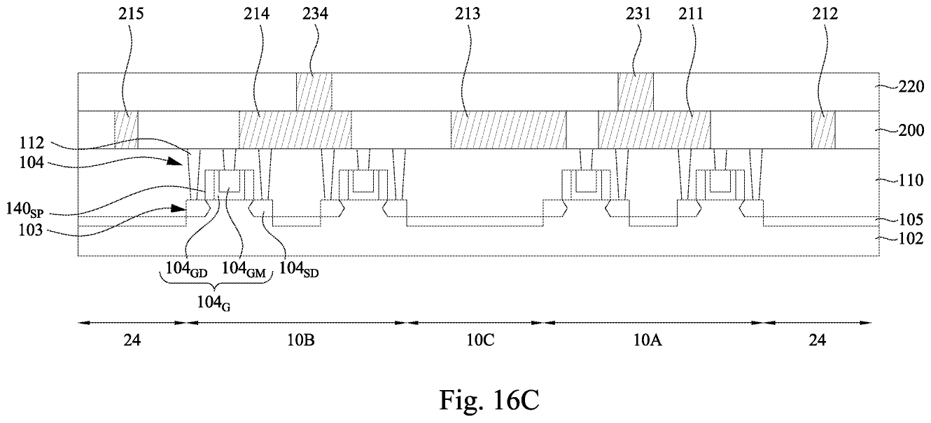

FIG. 16A is a perspective view of a wafer in accordance with some embodiments of the present disclosure. FIG. 16B is a top view of a wafer in accordance with some embodiments of the present disclosure. FIG. 16C is a cross-sectional view of a wafer in accordance with some embodiments of the present disclosure. In greater detail, FIG. 16C is a cross-sectional view along line C-C of FIG. 16B. It is noted that some elements of FIGS. 16A to 16C are similar to those described in FIGS. 3A to 15, such elements are labeled the same, and relevant details will not be repeated for brevity.

The structure of FIGS. 16A to 16C is different from the structure discussed with respect to FIGS. 3A to 15, in that the alignment mark 213 may extend into the first area 10A of the die region 10. That is, the alignment mark 213 may overlap both the first area 10A and the stitching zone 10C of the die region 10. In some embodiments, the alignment mark 213 does not extend into the second area 10B. In FIG. 16C, the alignment mark 213 may vertically overlap at least one device 104 within the first area 10A, while the alignment mark 213 does not overlap the device 104 within the second area 10B.

The alignment mark 213 may be formed by, for example, designing the alignment mark pattern P13 of the photomask MA1, such that the exposed region E13 of the photoresist layer PR1 of FIG. 5A overlaps both the first area 10A and the stitching zone 10C of the die region 10. Therefore, the corresponding opening O3 formed in the IMD layer 200 would overlap both the first area 10A and the stitching zone 10C of the die region 10, and the resulting pattern of the alignment mark 213 is shown in FIGS. 16A to 16C.

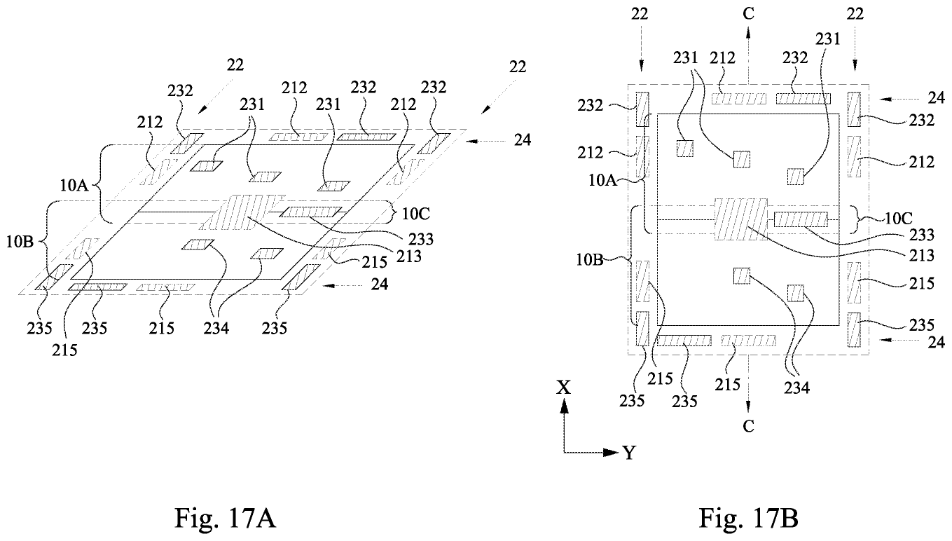

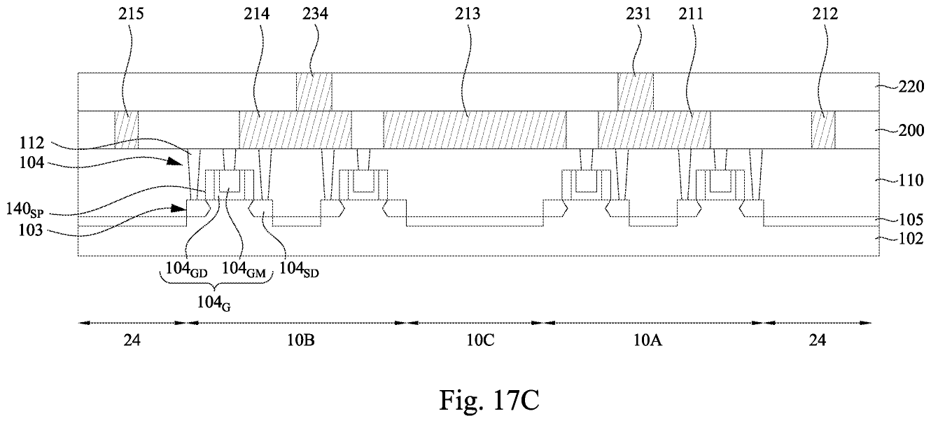

FIG. 17A is a perspective view of a wafer in accordance with some embodiments of the present disclosure. FIG. 17B is a top view of a wafer in accordance with some embodiments of the present disclosure. FIG. 17C is a cross-sectional view of a wafer in accordance with some embodiments of the present disclosure. In greater detail, FIG. 17C is a cross-sectional view along line C-C of FIG. 17B. It is noted that some elements of FIGS. 17A to 17C are similar to those described in FIGS. 3A to 15, such elements are labeled the same, and relevant details will not be repeated for brevity.

The structure of FIGS. 17A to 17C is different from the structure discussed with respect to FIGS. 3A to 15, in that the alignment mark 213 may extend into the first area 10A and the second area 10B of the die region 10. That is, the alignment mark 213 may overlap the first area 10A, the second area 10B, and the stitching zone 10C of the die region 10. In FIG. 16C, the alignment mark 213 may vertically overlap at least one device 104 within the first area 10A, and may vertically overlap at least one device 104 within the second area 10B. The alignment mark 213 is formed within a portion of the first area 10A that is free of layout pattern (e.g., metal features 211). Such configuration may improve the process flexibility.

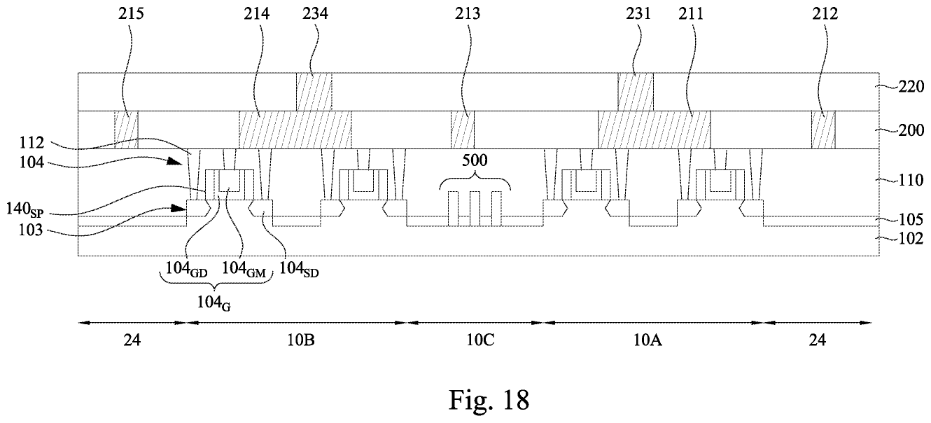

FIG. 18 is a cross-sectional view of a wafer in accordance with some embodiments of the present disclosure. FIG. 18 is similar to FIG. 13C, the difference between FIG. 18 and FIG. 13C is that the structure of FIG. 18 includes an alignment mark 500 within the stitching zone 10C. In some embodiments, the alignment mark 500 may be formed in a same process as forming the fins 103. That is, the alignment mark 500 may be formed by patterning the substrate 102 using photolithography and etching techniques. Accordingly, the alignment mark 500 may include a same material as the fins 103, and top surface of the alignment mark 500 may be substantially level with top surfaces of the fins 103. In some embodiments, the alignment mark 500 may be used to aligning photomask (e.g., the photomasks MA1 to MA4 discussed above) during an exposure process. The alignment mark 213 is formed within portions of the first area 10A and the second area 10B that is free of layout pattern (e.g., metal features 211 and 214). Such configuration may improve the process flexibility.

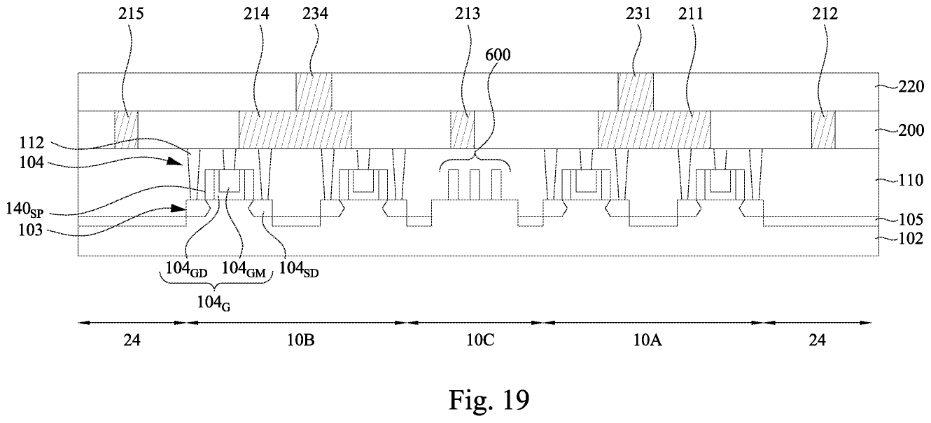

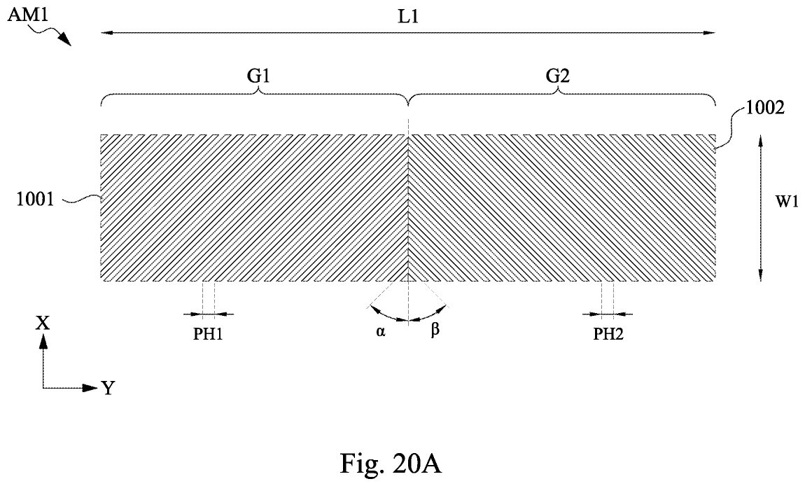

FIG. 19 is a cross-sectional view of a wafer in accordance with some embodiments of the present disclosure. FIG. 19 is similar to FIG. 13C, the difference between FIG. 19 and FIG. 13C is that the structure of FIG. 19 includes an alignment mark 600 within the stitching zone 10C. In some embodiments, the alignment mark 600 may be formed in a same process as forming the gate structures 104G. In some embodiments, the alignment mark 600 may include a same material as the gate structures 104G, and top surface of the alignment mark 600 may be substantially level with top surfaces of the gate structures 104G. In other embodiments, the alignment mark 600 may include polysilicon. In some embodiments, the alignment mark 600 may be used to aligning photomask (e.g., the photomasks MA1 to MA4 discussed above) during an exposure process.

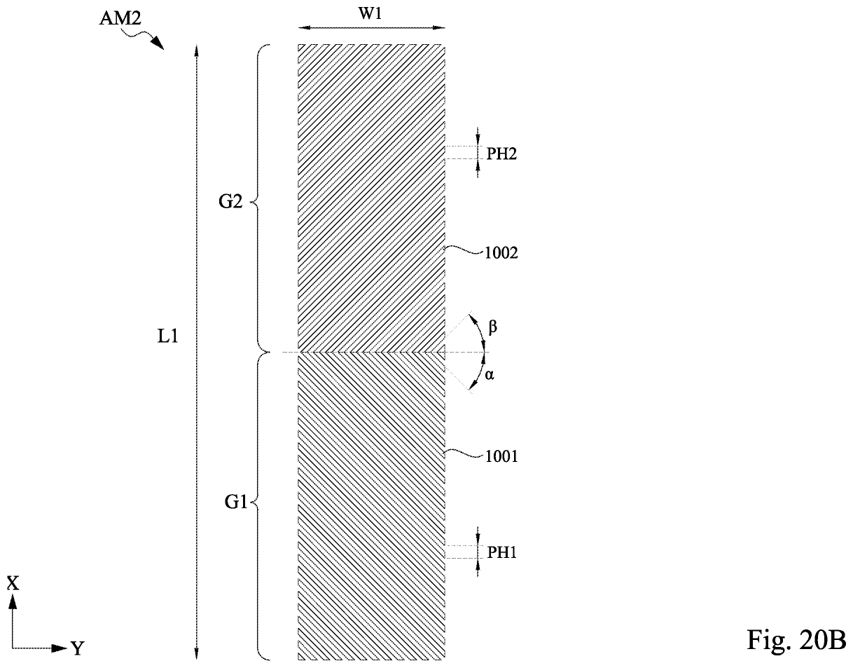

FIGS. 20A, 20B, 21A, 21B, 22A, and 22B are top profiles of alignment marks in accordance with some embodiments of the present disclosure. It is noted that, the shapes of the alignment marks 212, 213, 215, 232, 233, 235, 500, and 600 discussed above are merely used to explain, the actual profiles of the alignment marks 212, 213, 215, 232, 233, 235, 500, and 600 may vary with embodiments. FIGS. 20A, 20B, 21A, 21B, 22A, and 22B illustrate possible embodiments of the alignment marks 212, 213, 215, 232, 233, 235, 500, and 600 as discussed above.

FIGS. 20A and 20B illustrate a first type of alignment mark. In FIG. 20A, shown there is an alignment mark AM1 having a lengthwise direction along X direction. In FIG. 20B, shown there is an alignment mark AM2 having a lengthwise direction along Y direction. Each of the alignment marks AM1 and AM2 includes a first grating G1 of features 1001 and a second grating G2 of features 1002. The features 1001 are periodic structures extending in a first direction, the first direction being at a first angle α with respect to the center line between the first grating G1 and the second grating G2, in which −20°<α<−65°. The features 1002 are periodic structures extending in a second direction, the first direction being at a second angle β with respect to the center line between the first grating G1 and the second grating G2, in which 20°<β<65°. The alignment marks AM1 and AM2 each has a length L1 in a range from about 150 μm to about 170 μm, and a width W1 in a range from about 5 μm to about 80 μm. The features 1001 include a fixed pitch PH1 in a range from about 2.0 μm to about 3.5 μm. The features 1002 include a fixed pitch PH2 in a range from about 2.0 μm to about 3.5 μm.

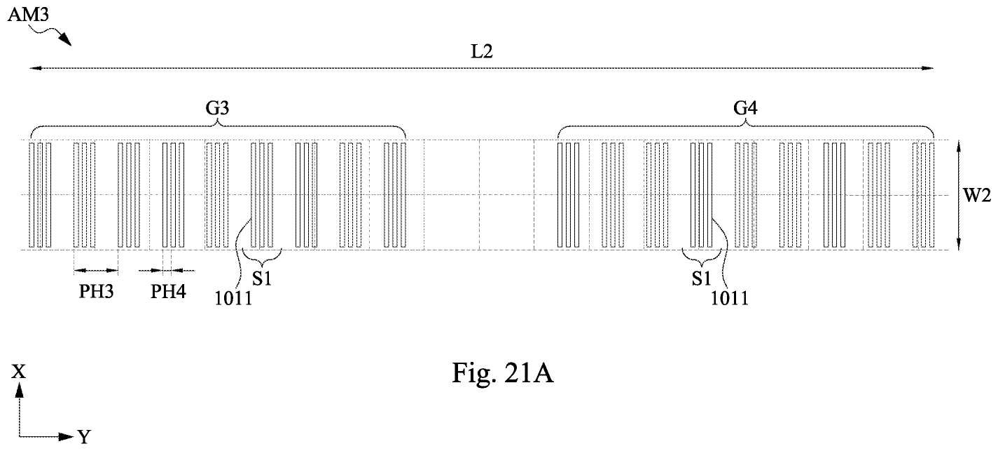

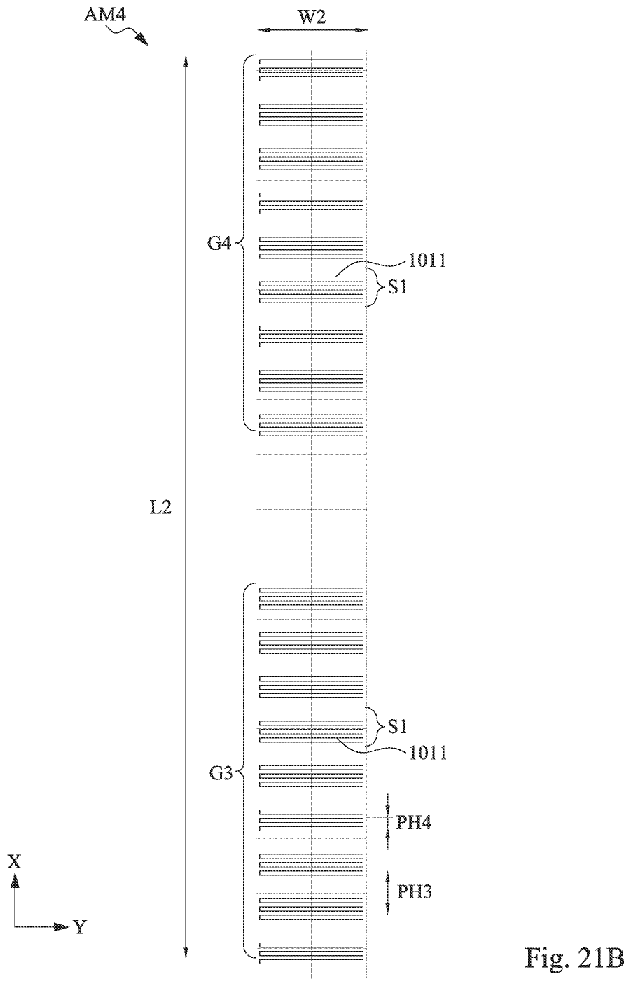

FIGS. 21A and 21B illustrate a second type of alignment mark. In FIG. 21A, shown there is an alignment mark AM3 having a lengthwise direction along X direction. In FIG. 21B, shown there is an alignment mark AM4 having a lengthwise direction along Y direction. Each of the alignment marks AM3 and AM4 includes a first grating G3 and a second grating G4. The first grating G3 may be similar to the second grating G4. For example, the first grating G3 and the second grating G4 each includes a plurality of feature groups S1 arranged periodically, and each feature group S1 includes a plurality of features 1011 arranged periodically. The pitch PH3 between two adjacent feature groups S1 is in a range from about 10 μm to about 20 μm. The pitch PH4 between two adjacent features 1011 is less than the pitch PH3. The distance between the first grating G3 and the second grating G4 may be greater than the pitch PH3. The alignment marks AM3 and AM4 each has a length L2 in a range from about 300 μm to about 400 μm, and a width W2 in a range from about 5 μm to about 80 μm.

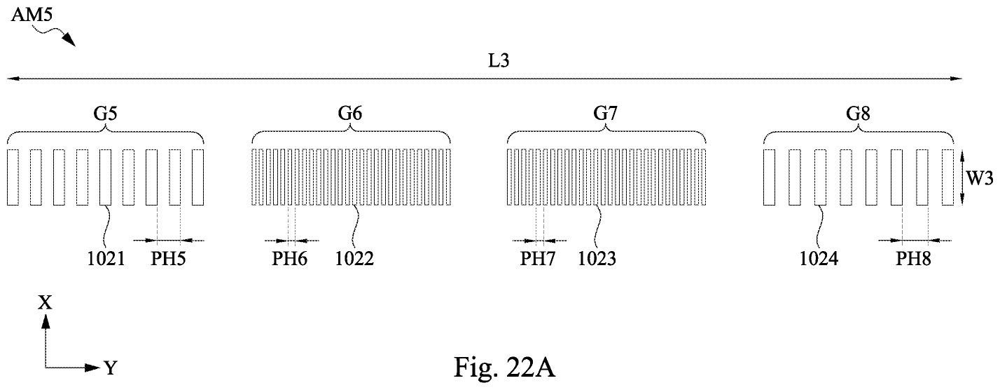

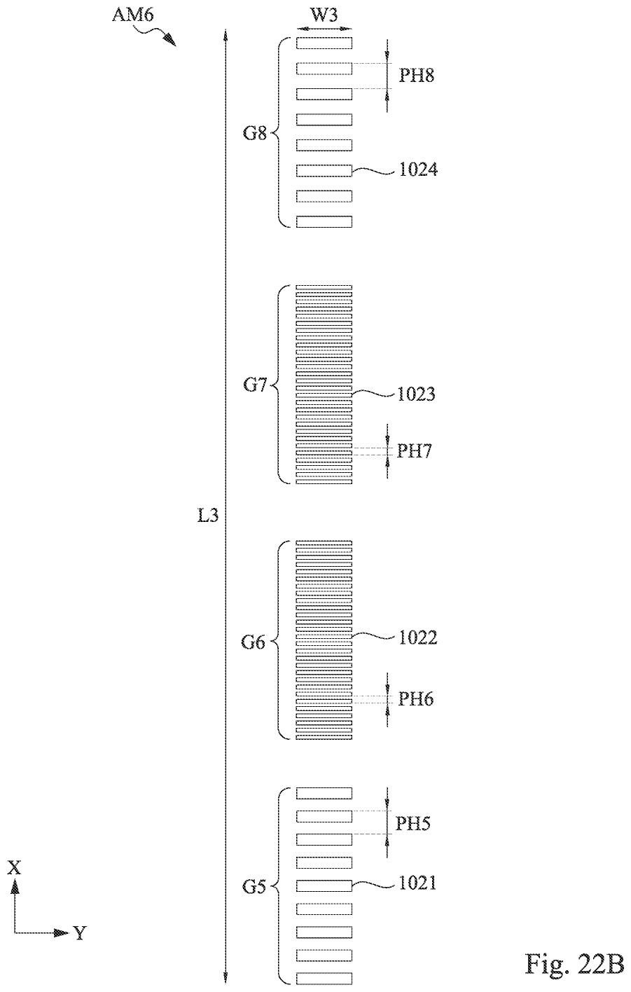

FIGS. 22A and 22B illustrate a third type of alignment mark. In FIG. 22A, shown there is an alignment mark AM5 having a lengthwise direction along X direction. In FIG. 22B, shown there is an alignment mark AM6 having a lengthwise direction along Y direction. Each of the alignment marks AM5 and AM6 includes a first grating G5, a second grating G6, a third grating G7, and a fourth grating G8. The first grating G5 includes a plurality of features 1021 arranged periodically, the second grating G6 includes a plurality of features 1022 arranged periodically, the third grating G7 includes a plurality of features 1023 arranged periodically, and the fourth grating G8 includes a plurality of features 1024 arranged periodically. The pitch PH5 between two adjacent features 1021 is in a range from about 1 μm to about 20 μm, the pitch PH6 between two adjacent features 1022 is in a range from about 1 μm to about 20 μm, pitch PH7 between two adjacent features 1023 is in a range from about 1 μm to about 20 μm, and pitch PH8 between two adjacent features 1024 is in a range from about 1 μm to about 20 μm. In some embodiments, pitch PH5 is equal to pitch PH8, and pitch PH6 is equal to pitch PH7, in which pitches PH5 and PH8 are less than pitches PH6 and PH7. The alignment marks AM5 and AM6 each has a length L3 in a range from about 700 μm to about 700 μm, and a width W3 in a range from about 5 μm to about 80 μm.

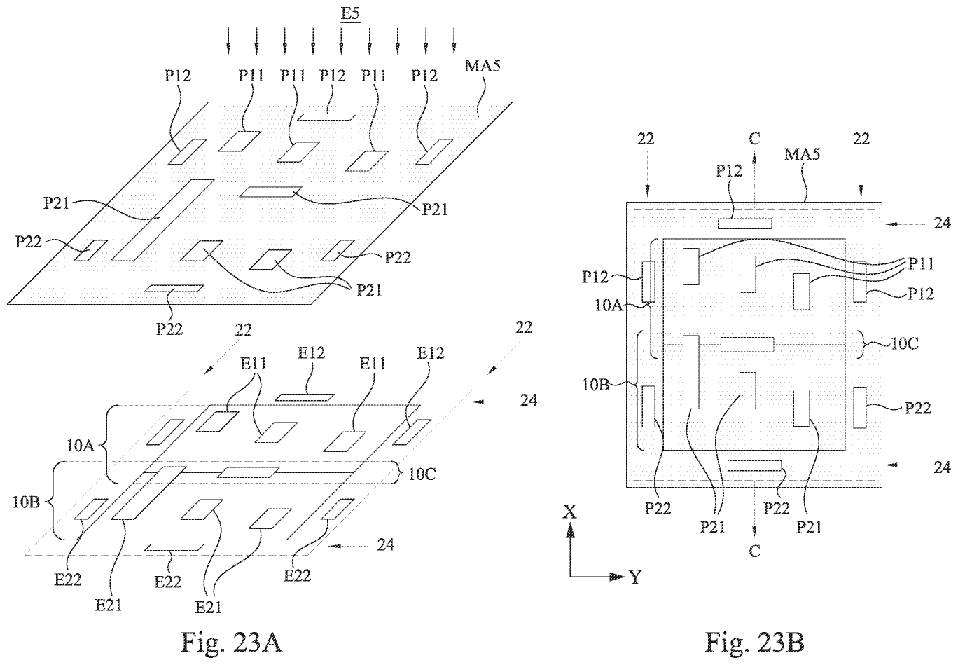

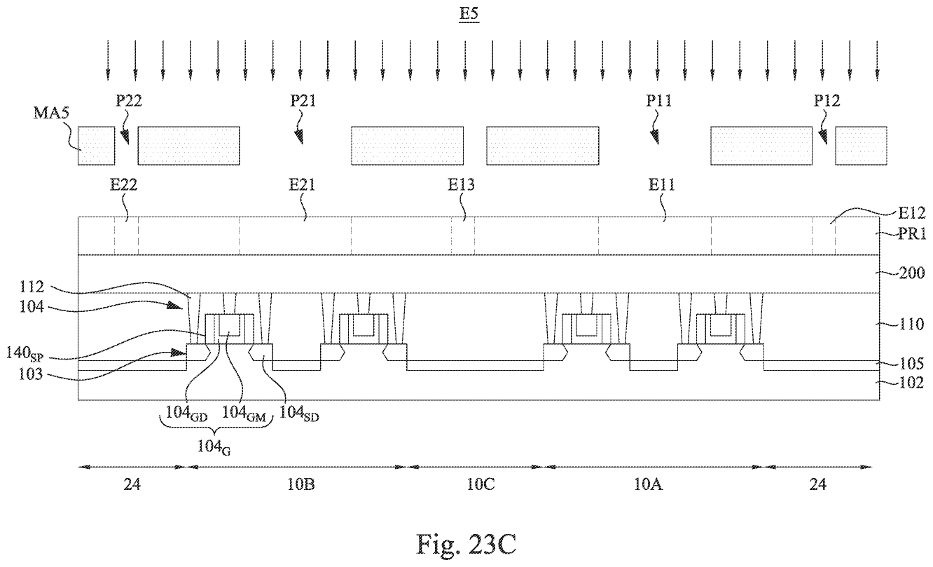

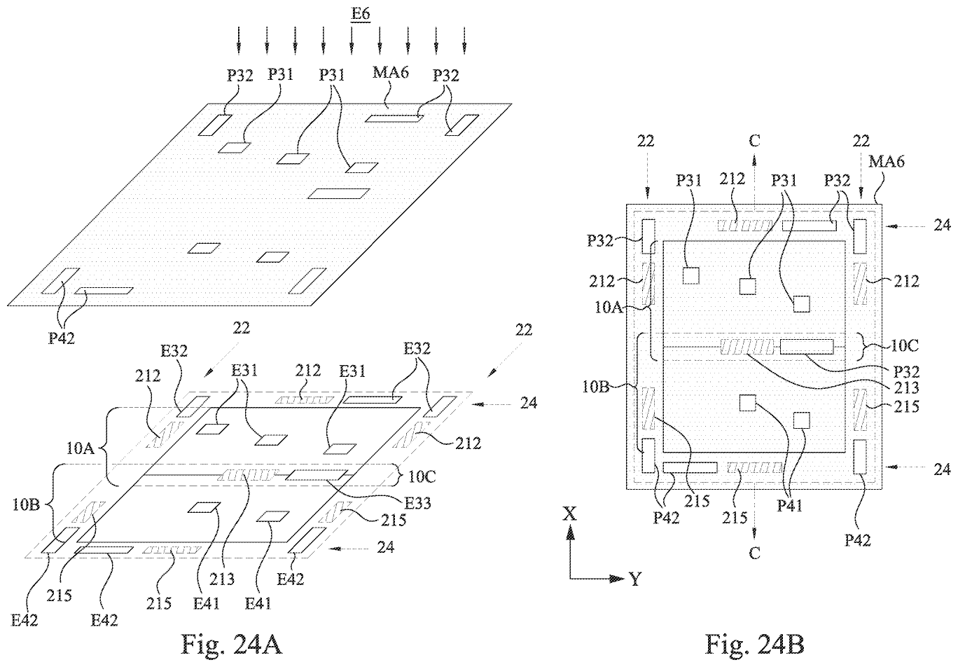

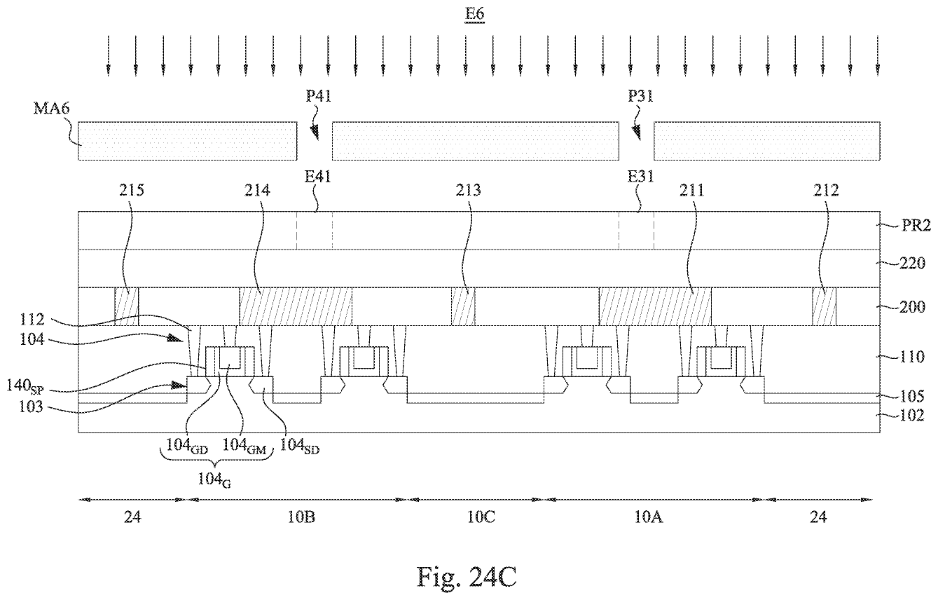

FIGS. 23A to 24C illustrate a semiconductor die in various stages of fabrication in accordance with some embodiments of the present disclosure. It is noted that some elements of FIGS. 23A to 24C are similar to those described with respect to FIGS. 3A to 15, such elements are labeled the same, and relevant details will not be repeated for brevity.

Reference is made to FIGS. 23A, 23B, and 23C, in which FIG. 23A is a perspective view of a wafer, FIG. 23B is a top view of a wafer, and FIG. 23C is a cross-sectional view along line C-C of FIG. 23B, respectively. FIGS. 23A to 23C illustrate using a single exposure process E5 to the photoresist layer PR1 through a photomask MA5. That is, different from the processes as described in FIGS. 5A to 6C where the photoresist layer PR1 within a die region 10 is exposed in two steps (e.g., two photomasks and two exposure processes), in FIGS. 23A to 23C the photoresist layer PR1 within an entire region of the die region 10 is exposed through a single exposure process E5 through a single photomask MA5.

For example, the patterns of the photomask MA5 may be transferred to the photoresist layer PR1 within the entire region of the die region 10. In greater detail, the photomask MA5 may include the patterns P11, P12, and P13 of the photomask MA1 (see FIGS. 5A to 5C) and the patterns P21 and P22 of the photomask MA2 (see FIGS. 6A to 6C). Accordingly, during the exposure process E5, exposed regions E11, E12, E13, E21, and E22 may be formed in the photoresist layer PR1. The structure may undergo the processes as described in FIGS. 7 to 8C, and the resulting structure may be the same as the structure shown in FIGS. 8A to 8C.

Reference is made to FIGS. 24A, 24B, and 24C, in which FIG. 24A is a perspective view of a wafer, FIG. 24B is a top view of a wafer, and FIG. 24C is a cross-sectional view along line C-C of FIG. 24B, respectively. FIGS. 24A to 24C illustrate using a single exposure process E6 to the photoresist layer PR2 through a photomask MA6. That is, different from the processes as described in FIGS. 10A to 11C where the photoresist layer PR2 within a die region 10 is exposed in two steps (e.g., two photomasks and two exposure processes), in FIGS. 24A to 24C the photoresist layer PR2 within an entire region of the die region 10 is exposed through a single exposure process E6 through a single photomask MA6.

For example, the patterns of the photomask MA6 may be transferred to the photoresist layer PR2 within the entire region of the die region 10. In greater detail, the photomask MA6 may include the patterns P31, P32, and P33 of the photomask MA3 (see FIGS. 10A to 10C) and the patterns P41 and P42 of the photomask MA4 (see FIGS. 11A to 11C). Accordingly, during the exposure process E6, exposed regions E31, E32, E33, E41, and E42 may be formed in the photoresist layer PR2. The structure may undergo the processes as described in FIGS. 12 to 15, and the resulting structure may be the same as the structure shown in FIG. 15.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a wafer alignment mark into stitching region, so as to stabilize the in product overlay. With such configuration, the device reliability may be improved.

In some embodiments of the present disclosure, a method includes forming a photoresist layer over a wafer; aligning a first photomask with a first area of the wafer; performing a first exposure process to a first portion of the photoresist layer within the first area of the wafer; aligning a second photomask with a second area of the wafer, wherein aligning the first photomask and aligning the second photomask are performed using an alignment mark within a stitching zone of the wafer, the stitching zone being an overlapping region of the first area and the second area; performing a second exposure process to a second portion of the photoresist layer within the second area of the wafer; and performing a development process to remove the first and second portions of the photoresist layer.

In some embodiments, the alignment mark non-overlaps portions of the first and second areas outside the stitching zone.

In some embodiments, the method further includes performing a die singulation process by sawing the wafer through scribe lines of the wafer to form a semiconductor die, wherein the alignment mark remain in the semiconductor die after the die singulation process is finished.

In some embodiments, the alignment mark extends into the first area of the wafer.

In some embodiments, the alignment mark non-overlaps a portion of the second area outside the stitching zone.

In some embodiments, the method further includes forming semiconductor devices over the first area and the second area of the wafer, and wherein the stitching zone of the wafer is free of semiconductor devices.

In some embodiments, the alignment mark non-overlaps the semiconductor devices.

In some embodiments, the alignment mark overlaps at least one of the semiconductor devices.

In some embodiments of the present disclosure, a method includes forming a photoresist layer over a wafer; performing a first exposure process, through a first photomask, to a first portion and a second portion of the photoresist layer within a first area of the wafer, wherein the first photomask has an alignment mark pattern correspond to the second portion of the photoresist layer; performing a second exposure process, through a second photomask, to a third portion of the photoresist layer within a second area of the wafer, wherein the second portion of the photoresist layer is within a stitching zone of the wafer, the stitching zone being an overlapping region of the first area and the second area; and performing a development process to remove the first, second, and third portions of the photoresist layer to form a patterned photoresist layer.

In some embodiments, the method further includes forming a dielectric layer over the wafer prior to forming the photoresist layer; performing an etching process to the dielectric layer through the patterned photoresist layer to form openings in the dielectric layer, wherein a pattern of the openings within the stitching zone of the wafer corresponds to the alignment mark pattern of the first photomask; and filling the openings of the dielectric layer with a material, wherein the material filled in the openings within the stitching zone of the wafer forms an alignment mark.

In some embodiments, the method further includes performing a die singulation process by sawing the wafer through scribe lines of the wafer to form a semiconductor die, wherein the alignment mark remain in the semiconductor die after the die singulation process is finished.

In some embodiments, the second portion of the photoresist layer extends into the first area of the wafer.

In some embodiments, the second portion of the photoresist layer non-overlaps portions of the first and second areas outside the stitching zone.

In some embodiments, the method further includes forming semiconductor devices over the first area and the second area of the wafer, and wherein the stitching zone of the wafer is free of semiconductor devices.

In some embodiments, the second portion of the photoresist layer non-overlaps the semiconductor devices.

In some embodiments of the present disclosure, a method includes forming semiconductor devices within a first device region and a second device region of a substrate, and absent within a non-device region of a substrate, wherein the non-device region separates the first device region from the second device region; forming an alignment mark over the non-device region of the substrate, wherein a portion of the alignment mark extends into the first device region of the substrate; and forming features over the first and second device regions using the alignment mark.

In some embodiments, the non-device region is a strip region extending continuously from one side of the semiconductor die to another side of the semiconductor die.

In some embodiments, the portion of the alignment mark vertically overlaps at least one of the semiconductor devices.

In some embodiments, the method further includes forming a back-end-of-line (BEOL) structure over the semiconductor devices, the BEOL structure comprises a dielectric layer and metal features in the dielectric layer, wherein the alignment mark is formed within the dielectric layer.

In some embodiments, the alignment mark comprises a grating of periodic structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a photoresist layer over a wafer;
aligning a first photomask with a first area of the wafer;
performing a first exposure process to a first portion of the photoresist layer within the first area of the wafer;
aligning a second photomask with a second area of the wafer, wherein aligning the first photomask and aligning the second photomask are performed using an alignment mark within a stitching zone of the wafer, the stitching zone being an overlapping region of the first area and the second area;
performing a second exposure process to a second portion of the photoresist layer within the second area of the wafer; and
performing a development process to remove the first and second portions of the photoresist layer.

2. The method of claim 1, wherein the alignment mark non-overlaps portions of the first and second areas outside the stitching zone.

3. The method of claim 1, further comprising performing a die singulation process by sawing the wafer through scribe lines of the wafer to form a semiconductor die, wherein the alignment mark remain in the semiconductor die after the die singulation process is finished.

4. The method of claim 1, wherein the alignment mark extends into the first area of the wafer.

5. The method of claim 4, wherein the alignment mark non-overlaps a portion of the second area outside the stitching zone.

6. The method of claim 1, further comprising forming semiconductor devices over the first area and the second area of the wafer, and wherein the stitching zone of the wafer is free of semiconductor devices.

7. The method of claim 6, wherein the alignment mark non-overlaps the semiconductor devices.

8. The method of claim 6, wherein the alignment mark overlaps at least one of the semiconductor devices.

9. A method, comprising:
forming a photoresist layer over a wafer;
performing a first exposure process, through a first photomask, to a first portion and a second portion of the photoresist layer within a first area of the wafer, wherein the first photomask has an alignment mark pattern correspond to the second portion of the photoresist layer;
performing a second exposure process, through a second photomask, to a third portion of the photoresist layer within a second area of the wafer, wherein the second portion of the photoresist layer is within a stitching zone of the wafer, the stitching zone being an overlapping region of the first area and the second area; and
performing a development process to remove the first, second, and third portions of the photoresist layer to form a patterned photoresist layer.

10. The method of claim 9, further comprising:
forming a dielectric layer over the wafer prior to forming the photoresist layer;
performing an etching process to the dielectric layer through the patterned photoresist layer to form openings in the dielectric layer, wherein a pattern of the openings within the stitching zone of the wafer corresponds to the alignment mark pattern of the first photomask; and
filling the openings of the dielectric layer with a material, wherein the material filled in the openings within the stitching zone of the wafer forms an alignment mark.

11. The method of claim 10, further comprising performing a die singulation process by sawing the wafer through scribe lines of the wafer to form a semiconductor die, wherein the alignment mark remain in the semiconductor die after the die singulation process is finished.

12. The method of claim 9, wherein the second portion of the photoresist layer extends into the first area of the wafer.

13. The method of claim 9, wherein the second portion of the photoresist layer non-overlaps portions of the first and second areas outside the stitching zone.

14. The method of claim 9, further comprising forming semiconductor devices over the first area and the second area of the wafer, and wherein the stitching zone of the wafer is free of semiconductor devices.

15. The method of claim 14, wherein the second portion of the photoresist layer non-overlaps the semiconductor devices.

16. A method, comprising:
forming semiconductor devices within a first device region and a second device region of a substrate, and absent within a non-device region of the substrate, wherein the non-device region separates the first device region from the second device region;
forming an alignment mark over the non-device region of the substrate, wherein a portion of the alignment mark extends into the first device region of the substrate; and
forming features over the first and second device regions using the alignment mark.

17. The method of claim 16, wherein the non-device region is a strip region extending continuously from one side of substrate to another side of the substrate.

18. The method of claim 17, wherein the portion of the alignment mark vertically overlaps at least one of the semiconductor devices.

19. The method of claim 16, further comprising forming a back-end-of-line (BEOL) structure over the semiconductor devices, the BEOL structure comprises a dielectric layer and metal features in the dielectric layer, wherein the alignment mark is formed within the dielectric layer.

20. The method of claim 16, wherein the alignment mark comprises a grating of periodic structures.
